(19) United States
(12) Patent Application Publication
(10) Pub. No.: US 2025/0110087 A1
(43) Pub. Date: Apr. 3, 2025

(54) SYSTEM AND METHOD FOR DETECTING SUBSTRATE CHANGE USING SOUND

(71) Applicants: XEROX CORPORATION, Norwalk, CT (US); NATIONAL RESEARCH COUNCIL OF CANADA, Ottawa (CA)

(72) Inventors: Sarah J. VELLA, Milton (CA); Silvio E. KRÜGER, Ottawa (CA); Edward G. ZWARTZ, Mississauga (CA); Alexandros VASILEIOU, Toronto (CA); Johann JUNGINGER, Toronto (CA); Hamed O. TABRIZI, North York (CA)

(73) Assignees: XEROX CORPORATION, Norwalk, CT (US); NATIONAL RESEARCH COUNCIL OF CANADA, Ottawa (CA)

(21) Appl. No.: 18/479,206

(22) Filed: Oct. 2, 2023

(51) Int. Cl. G01N 29/24; H10N 30/06; H10N 30/09

(52) U.S. Cl. CPC G01N 29/2437; H10N 30/06; H10N 30/09; G01N 2291/02854; G01N 2291/101

(57) ABSTRACT

Examples are disclosed herein relating to detecting a change in a substrate. A system can include a transducer that can be frequency matched to a substrate and to provide an electrical signal that can characterize a reflected sound wave by the substrate. The system can include an acoustic wave analysis system to detect a change in a physical characteristic of the substrate.

### FIELD OF THE DISCLOSURE

This disclosure relates generally to transducers, and more particularly, to detecting changes to a substrate or on a substrate as the result of physical and/or chemical processes.

### BACKGROUND OF THE DISCLOSURE

An ultrasonic transducer is a device that converts electrical energy into high-frequency sound waves and vice versa. It consists of a piezoelectric element that generates the sound waves through the piezoelectric effect. Transducers are used in a variety of applications such as non-destructive evaluation of objects and structures, medical diagnostic imaging (ultrasonography), measuring distance (e.g. Sound Navigation and Ranging (SONAR)), measuring acceleration (accelerometers), or measuring the flow of a liquid, to name a few. For example, ultrasonic detection can be carried out in a few different ways. In one implementation, a pulse-echo approach is used. In this implementation, a piezoelectric element (material) of the ultrasonic transducer converts electrical signals into mechanical vibrations to generate sound waves (ultrasonic waves) (send mode or pulse mode) and mechanical vibrations into electrical signals (receive mode) to receive reflected sound waves. The sound waves can be generated by applying a voltage across the piezoelectric material causing the material to vibrate to emit the sound waves. The same piezoelectric material can receive sound waves (the reflected sound waves) and provide one or more electrical signals representative of the received sound waves, which can be referred to as acoustic signals. In some examples, an amplitude or voltage of the acoustic signals can be plotted as a function of time to produce a time domain graph. The analysis of the echoes in the time domain can be used to calculate features such as the thickness of a substrate, thickness of different layers of materials, or location of defects.

A typical structure of an ultrasonic transducer includes a piezoelectric material (element) located between two electrodes, an acoustic impedance matching layer, and a backing material. The electrodes are used to establish a voltage across the piezoelectric element to generate the ultrasonic waves and to convert received ultrasonic waves into an electrical signal. Ultrasonic waves can be generated in both directions, that is, from both faces of the piezoelectric element. An ideal transducer would have 100% of the waves emitted in one direction and 0% of waves emitted in the other direction. The acoustic impedance matching layer provides an intermediate layer that minimizes the loss of acoustic energy as it passes from one medium to the next medium of materials with different acoustic impedances; the acoustic impedance matching layer generally has an acoustic impedance value that is between that of the two materials it bridges. For example, on an emission face of the piezoelectric element, the acoustic impedance matching layer is used to improve a transfer of sound energy from the piezoelectric element into an environment being tested (e.g. human tissue, water, etc.) On the other face of the piezoelectric element, a backing layer is used to absorb the sound waves that might otherwise interfere with desired received signals. The backing material can have the same acoustic impedance as the piezoelectric element, to allow all acoustic energy (sound wave) to transfer into the backing material and also be attenuated by the backing material. The backing layer can be composed of a dense particle, e.g. tungsten dispersed in an epoxy.

### SUMMARY OF THE DISCLOSURE

Various details of the present disclosure are hereinafter summarized to provide a basic understanding. This summary is not an extensive overview of the disclosure and is neither intended to identify certain elements of the disclosure nor to delineate the scope thereof. Rather, the primary purpose of this summary is to present some concepts of the disclosure in a simplified form prior to the more detailed description that is presented hereinafter.

According to an embodiment, a system can include a transducer that can be frequency matched to a substrate and to provide an electrical signal that can characterize a reflected sound wave by the substrate. The system can include an acoustic wave analysis system that can detect a change in a physical characteristic of the substrate.

In another embodiment, a system can include an ultrasonic transducer for detecting a change in a substrate that includes a first electrode, a second electrode, and a piezoelectric material between the first electrode and the second electrode, wherein the transducer is frequency matched to the substrate.

In yet another embodiment, a method can include forming a piezoelectric material between the first electrode and the second electrode, wherein the transducer is frequency matched to the substrate, and constructing a transducer with the formed piezoelectric material for monitoring the substrate.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is a block diagram of an example of an acoustic wave analysis system.

FIG. 2 is an example of a transducer emitting a sound wave at a number of materials (or substrates).

FIG. 3 is an example of a graph of acoustic pulses emitted and captured by a transducer.

FIGS. 4-5 are examples of graphs of a frequency spectrum of a resonance frequency of respective transducers having different resonance frequencies.

FIG. 6 is an example of acoustic signature graphs acquired using a 1 Megahertz (MHz) transducer.

FIG. 7 is an example of acoustic signature graphs acquired using a 0.5 MHz transducer.

FIG. 8 is yet another example of acoustic signature graphs acquired using a 1 MHz transducer.

FIG. 9 is an example of acoustic signature graphs for a transducer that is about 0.5 mm thick and with a resonance frequency of about 1.817 MHz.

FIG. 10 is an example of a resulting pattern of resonating frequencies of the 25.3 mm aluminum substrate (0.127 MHz) with the 1.817 MHz transducer.

FIG. 11 illustrates an example of a table with calculated frequency and corresponding calculated thickness of an aluminum substrate.

FIG. 12 is an example of acoustic signature graphs acquired using a 1.187 MHz transducer.

FIG. 13 is yet another example of acoustic signature graphs acquired using a 1.187 MHz transducer.

FIGS. 14-24 relate to examples illustrating changes in resonance frequency peaks due to changes in a substrate.

FIGS. 25-29 relate to examples illustrating how a resonance frequency of a transducer and a substrate shift in a presence of an additional layer on a substrate.

FIG. 30 illustrates a table with parameters used for modeling.

FIG. 31 is an example of a frequency-thickness graph.

FIG. 32 is another example of a frequency-thickness graph.

FIG. 33 illustrates a table summarizing observed shifts with respect to one or more examples, as disclosed herein.

FIG. 34 is an example of a method for determining whether a thickness of a substrate has changed.

FIG. 35 depicts an example computing environment that can be used to perform one or more actions according to an aspect of the present disclosure.

FIG. 36 depicts a cloud computing environment that can be used to perform one or more actions according to an aspect of the present disclosure.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments of the present disclosure relate to detecting substrate physical and/or chemical characteristic changes. Exemplary physical characteristic changes can include, for example, a change in thickness, including a decrease in thickness or increase in thickness, such as by addition or formation of a layer (or a material) on the substrate. Sound waves can be used to measure changes in thickness in a material (or substrate), or if an additional layer has been formed on the material. When the material is thin (e.g., of about 200 micrometers (μm), 500 μm, 1 millimeter (mm), or 2 mm) (relative to an acoustic wavelength), the change in thickness of a material (or substrate) is small (e.g., change in thickness could range from about 2 mm to about 5 μm), or the accumulation of an additional layer is small (e.g., about 10 μm, 200 μm, 500 μm, 1 mm, or 2 mm), or the accumulation of a non-continuous layer of material on the substrate is small, and thus it can be difficult to accurately measure the thickness of thin substrates or changes in thickness. Likewise, when the material is thick, small changes in a thickness of the material or thin layers of an additional material being formed on the material make it difficult to determine the material thickness or changes in the thickness. This is because echoes (signal responses representative of reflected sound from the substrate) in a time-domain overlap, and thus are not sufficiently distinct for accurate substrate thickness measurement/computation. For example, measuring thickness of steel of less than 1 mm with a typical ultrasonic transducer of 5 Megahertz (MHz) will result in the echoes being overlapped and it may be difficult to determine their time of arrival in the time domain. Techniques can be used to analyze an acoustic signature (that is an acoustic response of the substrate) in a frequency domain, however, a resonance frequency of the substrate and a device measuring the substrate can result in a complex (splitting) frequency pattern. The complex frequency pattern makes it difficult to measure the thickness of the substrate as well.

Transducers, such as piezoelectric transducers (also known as piezo transducers) can be used to emit a sound wave toward the substrate and capture a reflected sound wave from the substrate (material). However, a resonance frequency of the substrate (material) can destructively interfere with a resonance frequency of the piezo transducer, creating the complex frequency pattern (response) in the frequency domain. This is further complicated when another layer, for example, an accretion of ice, is added to (or formed on) the substrate as the other layer can shift a frequency response (the complex frequency pattern). The complex frequency pattern can have dominant components (that can be relatively close to each other, in some instances), making the analysis in the frequency domain of substrate difficult. This can result in inaccurate calculations of change in the substrate, internally (e.g., change in material density), or on its surface (addition of a surface layer on the substrate, for example, ice). A bandwidth of the transducer is another challenge so that the device is sensitive enough to substrate changes (that is detect substrate changes in thin materials or when the substrate change is relatively small). The bandwidth describes the range of frequencies to which the piezo-transducer is sensitive. The larger the bandwidth, the more sensitive the transducer can be in a wider range of frequencies. Furthermore, existing techniques use transducers (e.g., ultrasound transducers) as a standalone instrument that is separate from an object (the substrate) that is being analyzed. Different existing methods can be used to attempt to minimize a difference in acoustic impedance between the transducer and the substrate being analyzed, for example, by selection of transducer characteristics with respect to size and frequency, and by adding an acoustic impedance matching layer to the transducer.

According to the examples disclosed herein, a transducer can be configured to match the frequency of the substrate and thus the transducer can be frequency matched to the substrate. Frequency matching of the substrate and the transducer can refer to the transducer having a frequency bandwidth (frequency range) that includes a resonance frequency of the substrate. The transducer can include a piezoelectric material. The piezoelectric material can have a resonance frequency and a bandwidth range (e.g., a range of frequencies at which the piezoelectric material responds). Because the transducer includes the piezoelectric material, the transducer can have a bandwidth range that is based on the piezoelectric material and thus associated with the resonance frequency of the piezoelectric material. In some examples, the transducer can include a backing material. The backing material can impact the resonance frequency of the piezoelectric material, the bandwidth of the transducer, and a sensitivity of the transducer. The backing material also has the effect of dampening the ringing of the transducer and attenuating acoustic waves that emanate from a back side of the transducer. By including the backing material, the bandwidth range of the piezoelectric material can be broadened (e.g., increased). Thus, the bandwidth range of the transducer can be broadened with the use of the backing material, in some instances, to include the bandwidth range of the substrate. The impact of the backing layer on the resonance frequency of the transducer can be characterized before it is matched to a substrate and incorporated into a device; e.g., the resonance frequency of the assembled transducer would be known. Accordingly, the bandwidth range of the transducer is based on properties of the piezoelectric material and/or backing plate. For example, the properties of the piezoelectric material and/or backing plate can change cutoff frequencies (e.g., lower and upper frequency limits at which the transducer responds).

The bandwidth range of the transducer can be compatible with expected changes in the resonance frequency of the substrate. For example, if the substrate is expected to decrease its thickness (e.g. because of corrosion) the resonance frequency of the substrate can increase. The bandwidth range of the transducer can include frequencies that cover the expected increase of the resonance frequency of the substrate in order to be sensitive to the change. In some examples, the resonance frequency of the transducer can be chosen to be higher or lower than the initial resonance frequency of the substrate, depending if this resonance frequency is expected to increase (e.g. because of corrosion) or decrease (e.g. because of ice accretion).

In some examples, the piezoelectric material can be designed to dampen an acoustic or electric excitation, a characteristic also known as low Q, and in this way cause the transducer to respond in a wide band of frequencies. For example, a piezoelectric material with a resonance frequency at about 2 MHz could be responsive to excitations between about 1 and about 3 MHz, and consequently cause the transducer to cover the changes in the frequency of the substrate in this range. By matching the resonance frequency of the transducer to the resonance frequency of the material being monitored (detected) eliminates or mitigates interference of the resonance frequency of the substrate with the resonance frequency of the transducer. As such, more accurate detection in changes in thin substrates or small changes in substrate density can be made, as well as allow for detection of a formed layer on the substrate, such as ice in contrast to existing substrate change detection techniques. The use of a frequency range close to the resonance frequency of the substrate with or without additional layers on the substrate is also advantageous when the substrate and/or the additional layer is made of a heterogeneous material. This is because the heterogeneous materials, like composites or ice, tend to attenuate higher frequencies that should be used if time domain echo resolution is required. Instead, lower resonant frequencies are not as attenuated by composite or heterogeneous materials; so although lower frequencies are not sufficiently distinct in the time domain, analysis in the frequency domain is acceptable.

Because the resonance frequencies of the transducer and substrate are matched this can create a prominent peak and eliminate the complex frequency pattern (peaks) in the frequency domain. Interference from mismatched resonance frequencies or frequencies of higher harmonics are reduced or eliminated that can cause destructive interference. For example, if the substrate had a resonance frequency that was a multiple or greater than the resonance frequency of the transducer, this can result in a frequency spectrum (in the frequency domain) with multiple dominant peaks that are relatively close to each other making it difficult to know which of the dominant peaks should be selected for analysis for substrate change detection. The resonance frequency matching of the transducer and substrate reduces or eliminates the destructive interference of the substrate, which leads to a prominent peak in the frequency domain. A prominent peak in the frequency domain can refer to a local maximum in a magnitude of the frequency spectrum, indicating a dominant frequency component within a signal that is representative of a response of the transducer to the substrate. The local maximum is a value (e.g., amplitude) that is greater than neighboring values (e.g., amplitudes) and thus can differentiate the prominent peak from other parts of the frequency spectrum that can have high values but are not greater than neighboring values. The magnitude of the frequency spectrum indicates how strong or prominent a particular frequency is within the signal, and the dominant frequency component indicates that the signal has a frequency with a stronger presence than other frequencies of the signal.

Examples disclosed herein can be used to simplify analysis in the frequency domain (for substrate changes), and improves substrate change detection in contrast to existing frequency domain analysis techniques, which require analysis of the complex frequency pattern. Furthermore, because resonance frequency interference from the substrate is eliminated (or reduced) this allows the transducer to be more sensitive to substrate changes or detection of accumulated materials on the substrate. Changes in thickness of the substrate or by addition of material to the substrate causes changes in the frequency of the substrate, resulting in either a shift of a prominent peak or dominant peak splitting in the frequency domain. For example, when the thickness of the substrate changes, this changes or adjusts a frequency response of the substrate. The change in frequency response of the substrate shifts the prominent peak in the frequency domain. The shifting of the prominent peak and dominant peak splitting can be more readily (and accurately) detected according to the examples disclosed herein. Enabling evaluation in the frequency domain without the destructive interference from the substrate is advantageous, in some instances, as it simplifies the analysis and improves the sensitivity of ultrasound detection (or monitoring). Examples are presented herein relating to detecting physical changes, such as a change in thickness of a substrate (e.g., through corrosion) and addition of another layer to the substrate (e.g., through electroplating, as an example). However, the examples disclosed herein and as such as the transducer of the present disclosure can be used for detecting other physical changes, which can include, but not limited to, cracks, delamination, accretion of another material, density (or change in density), and/or the like.

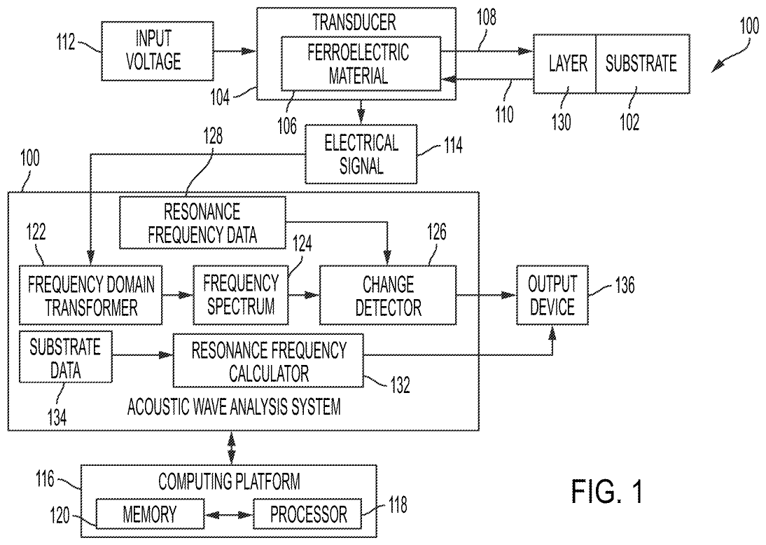

FIG. 1 is a block diagram of an example of an acoustic wave analysis system 100. The system 100 can be used to detect changes in a substrate 102, in some instances, used for detecting an accumulated material on the substrate (e.g., accretion of a material, for example, ice), or decrease in thickness of the substrate. The term “change” as used herein with respect to a substrate can include physical substrate changes. Examples are presented herein in which the physical substrate change is thickness, but other physical substrate changes caused by physical and/or chemical processes are contemplated within the present disclosure. The change in substrate thickness can include an increase or decrease in the substrate thickness. Increase in thickness of the substrate can refer to a formation or addition (accumulation) of a material (or substance) on a surface of the substrate. The added material can be referred to as an accumulated (or added) material. As an example, the accumulated material can be ice. For example, the thickness of the substrate can change, that is decrease, because of corrosion, delamination, cracking in the material (substrate), etc. The change in thickness may not need to be uniform. For example, corrosion of the substrate 102 can cause non-uniform pitting of the substrate 102. Pitting of the substrate 102 can cause a change in density, which can be detected according to one or more examples, as disclosed herein. Because the transducer is resonance frequency tuned or matched to the substrate that the transducer is to monitor this provides more accurate corrosion or delamination monitoring of the substrate, or detection of accumulated material on the substrate. In some examples, the substrate 102 is a portion of a pipeline (or metal object). It is understood that the substrate 102 can be any type of material that can change in thickness, including an increase in thickness (through addition or accumulation of material) or decrease in thickness. Thus, the examples herein should not be construed and/or limited to detecting changes in a metal material (or substrate), but can include other types of materials having no metal or some metal properties.

The system 100 includes a transducer 104 that can be configured with a piezoelectric material 106, as shown in FIG. 1. In some examples, the transducer 104 is a low-frequency piezo transducer. Low frequency transducers are less susceptible to acoustic attenuation which makes such transducers more compatible with non-uniform or composite substrates (e.g., carbon-fiber reinforced polymers) or heterogeneous added layers (e.g. ice accretion), than high frequency transducers. Example low frequency transducers can include transducers that can respond from about 0.1 to about 10 Megahertz (MHz), whereas high frequency transducers can respond at greater than 10 MHz frequencies. Typically, high frequency transducers are desired for detecting changes in thickness or defects in substrates because higher frequencies provide better resolution. By contrast, low-frequency transducers have a lower resolution and are not generally used for detecting substrate changes (e.g., caused by corrosion or accretion of ice) as the resolution of such devices is not as sufficient as a high frequency transducer.

In some examples, the transducer 104 is a non-ceramic transducer. Ceramic transducers can be difficult to manufacture with a particular thickness that matches a given substrate, which limits available frequencies of the ceramic transducers and therefore a range of substrate thicknesses for which such transducers can be used. Ceramic transducers are also rigid and brittle, limiting the substrates to which these devices could be successfully adhered. Another practical difficulty with ceramic transducers is their high acoustic impedance, which makes acoustic impedance matching with different substrates a challenge and requiring an acoustic impedance matching layer. In some examples, the transducer 104 can be fabricated (or made) with a composite piezoelectric material (the piezoelectric material 106) with a given thickness. The given thickness can be such that the transducer is tuned to match the substrate 102. Moreover, because the acoustic impedance of the transducer 104 is lower (when manufactured with the composite piezoelectric material) than ceramic transducers, it may be unnecessary to include an acoustic impedance matching layer ( ) which can simplify the device fabrication and architecture and can make the transducer 104 more compatible with different substrates. Moreover, because the piezoelectric material can be a composite material whose thickness can be tuned during fabrication (for example by 3D printing the material, or injection molding, or thermal pressing), the transducer 104 can be fabricated with a particular thickness making the transducer 104 more compatible with different substrates with different resonance frequencies.

The design and manufacture of piezoelectric ultrasonic transducers is separate from substrates on which such devices are to be used. Tuning a resonance frequency of ceramic piezoelectric transducers is difficult due to the nature in which such devices are manufactured. In some examples, the transducer 104 is manufactured with the piezoelectric material 106 that is the composite piezoelectric material. The given thickness can be defined during the fabrication process so that the transducer 104 is tuned to match the substrate 102. The fabrication process (e.g., tuning process) can include, for example, molding, pressing, or three-dimensional (3D) printing. As an example, using 3D printing allows for conformal contact of piezoelectric material (piezoelectric 106) with the substrate 102. 3D printing can be used to tune piezoelectric properties with the ability to design thickness and geometry that impact properties, such as resonance frequency or bandwidth of the transducer 104. The composite nature of the piezoelectric material allows for better acoustic impedance matching of ultrasonic transducers with a variety of substrates (polymeric, composite, metal, etc. . . . ), which can be implemented as the substrate 102.

For example, the transducer 104 can be manufactured with the composite piezoelectric material, as disclosed in International Patent Application Number PCT/US2022/021315, filed Mar. 22, 2022, and incorporated herein by reference in its entirety. Other techniques for transducer manufacturing are contemplated as part of this disclosure. The tuning process can be used to tune the resonance frequency of the transducer 104 to the resonance frequency of the substrate 102. For example, the piezoelectric material 106 can be fabricated with a geometry (e.g., shape) that once incorporated into the transducer 102 results in the transducer 102 being frequency matched with the substrate 102. In an example, a thickness or dimensionality of the piezoelectric material 106 can be selected during fabrication (or manufacturing) of the transducer 104 so that the thickness of the piezoelectric material 106 matches a thickness of the substrate 102 (corresponding to a resonance frequency match).

In some examples, the transducer 104 can be printed onto or into the substrate 102 (e.g., test object) and thus, in some implementations, the transducer 104 can be incorporated into the substrate 102, or associated with the substrate 102. Matching the resonance frequencies can make the substrate 102 “invisible” to a sound wave 108 (e.g. ultrasound wave) produced by the transducer 104, which eliminates or reduces interference of the sound waves 108 echoed in the substrate 102 with the sound waves 108 produced by the transducer 104 that are used (as reflected sound waves 110) for detecting or measuring substrate change. While examples are disclosed herein in which the transducer is a non-ceramic transducer, it is to be understood that in some instances (or implementations) a ceramic transducer can be used as well, which has been frequency matched to the resonance frequency of the substrate 102. Any type of transducer can be used as the transducer 104 that can be manufactured with a material that results in the transducer 104 being frequency matched to the substrate 102. Thus, for example, the transducer 104, in some instances, can be implemented as a ceramic transducer, a polymeric transducer, a composite transducer, etc.

In some examples, the piezoelectric material 106 can be formed with defined properties so that a bandwidth of the piezoelectric material 106 includes a frequency response of the substrate 102. The defined properties can include one of a thickness, an elasticity, a porosity, a composition, a density, and/or a shape of the piezoelectric material. For example, the piezoelectric material 106 can be provided with a given thickness resulting in the piezoelectric material 106 having the bandwidth that includes a resonance frequency or frequency range (bandwidth) of the substrate 102. In some examples, providing can include one of 3D printing, molding, or thermal pressing the piezoelectric material according to thickness criteria specifying the given thickness for the piezoelectric material 106. The transducer 104 can be constructed with the formed piezoelectric material 106 having the defined properties.

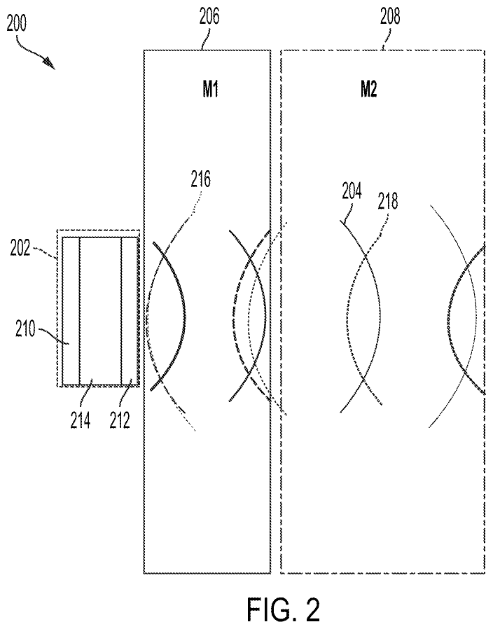

For example, electrodes (not shown in FIG. 1, but see, for example, FIG. 2) of the transducer 104 can be used to apply a voltage 112 across the piezoelectric material 106 to generate the sound wave 108, which can be used to interrogate the substrate 102. The substrate material 102 can be an electrode (e.g., a metal, a conductive polymer, etc.) provided it is sufficiently conductive, in some examples. Thus, in some instances, the substrate 102 can be both the electrode and the substrate at the same time. For example, if the substrate 120 is aluminum (e.g., as it may be in an airplane wing), the aluminum would be both the substrate (to which the transducer is attached) and one of the electrodes. In some examples, if instead the substrate were a conductive polymer, it could also be used as the electrode. In some examples, a conductive polymer can be used as the material 102 that has a conductive range from about 0.1 S/cm up to about 7×10\hat{ }5 S/cm. In some examples, the transducer 104 can be fabricated with the piezoelectric material 106, which results in the transducer 104 being frequency matched with the substrate 102. The sound wave 108 can be propagated to (or at the) substrate 102 and reflected by the substrate 102 back to the transducer 104 as the reflected sound wave 110, as shown in FIG. 1. In some instances, the piezoelectric material 106 can be used to capture the reflected sound wave 110 and output an electrical signal 114 characterizing the reflected sound wave 110. The electrical signal 114 can be received by the acoustic wave analysis system 100, as shown in FIG. 1. In some examples, the system 100 can cause the input voltage 112 to be generated.

The system 100 can be implemented using one or more modules, shown in block form in the drawings. The one or more modules can be in software or hardware form, or a combination thereof. In some examples, one or more aspects of the system 100 can be implemented (e.g., as machine readable instructions) on a computing platform 116. The computing platform 116 can include one or more computing devices selected from, for example, a desktop computer, a server, a controller, a blade, programmable logic controller (PLC) controller, a mobile phone, a tablet, a laptop, a personal digital assistant (PDA), and the like. The computing platform 116 can include a processor 118 and a memory 120. By way of example, the memory 120 can be implemented, for example, as a non-transitory computer storage medium, such as volatile memory (e.g., random access memory), non-volatile memory (e.g., a hard disk drive, a solid-state drive, a flash memory, or the like), or a combination thereof. The processor 118 can be implemented, for example, as one or more processor cores.

The memory 120 can store machine-readable instructions (e.g., which can include the system 100) that can be retrieved and executed by the processor 118. Each of the processor 118 and the memory 120 can be implemented on a similar or a different computing platform. In some instances, the computing platform 116 can be implemented in a cloud computing environment (for example, as disclosed herein) and thus on a cloud infrastructure. In such a situation, features of the computing platform 116 can be representative of a single instance of hardware or multiple instances of hardware executing across the multiple of instances (e.g., distributed) of hardware (e.g., computers, routers, memory, processors, or a combination thereof).

The system 100 includes a frequency domain transformer 122. The frequency domain transformer 122 can process the electrical signal 114 to analyze a frequency content of the electrical signal 114. For example, the frequency domain transformer 122 can implement FFT technique/method(s) to convert the electrical signal 114 from a time domain to the frequency domain to provide a frequency spectrum 124. Thus, the frequency domain transformer 122 can provide a frequency domain view of the time domain signal (the electrical signal 114). The frequency spectrum 124 can represent the electrical signal 114 as a plot of amplitude (or power) versus frequency content of the electrical signal 114. The frequency spectrum 124 can be analyzed, according to one or more examples, as disclosed herein, in some instances, to determine signal characteristics of the electrical signal 114. Signal characteristics can include, for example, dominant frequencies, harmonic components, noise levels, and/or frequency distribution.

For example, the system 100 can further include a substrate change detector 126. The substrate change detector 126 can process the frequency spectrum 124 to determine whether the substrate 102 has changed (e.g., in thickness, has an accumulated layer, etc.). For example, the frequency spectrum 124 can receive resonance frequency data 128 characterizing the resonance frequency or a resonance frequency range of the substrate 102. Because the transducer 104 and the substrate 102 are frequency-matched, the frequency spectrum 124 can exhibit or have a dominant frequency component, which can correspond to a resonance frequency of the substrate 102. The substrate change detector 126 can evaluate the frequency spectrum 124 to locate the prominent frequency therein, and thus with the substrate 102 being tested. Resonance frequencies are specific frequencies at which a material exhibits a high response or vibration and can be captured in the frequency domain.

The substrate change detector 126 can use the resonance frequency data 128 to locate the resonance frequency (the dominant frequency component) in the frequency spectrum. In some examples, the resonance frequency data 128 or other data includes a power or amplitude threshold value (or range) for the resonance frequency. For example, the substrate change detector 126 can use the threshold to avoid detection (identification) of a frequency in the frequency spectrum 124 that is a false positive or non-dominant frequency, and thus is not the resonance frequency of the substrate 102. Because the resonance frequency of the substrate 102 can be related to a thickness of the substrate 102 and a speed of sound through the substrate 102, the thickness of the substrate 102 can be calculated based on the speed of sound and the resonance frequency by the substrate change detector 126. The substrate change detector 126 can estimate the thickness of the substrate 102 based on the frequency. For example, substrate change detector 126 can divide the wavelength by two (2) to compute the thickness of the substrate 102. In some examples, the substrate change detector 126 is provided with the thickness of the substrate 102.

The thickness of the substrate 102 determined by the substrate change detector 126 (or provided as data) can define a baseline thickness. The substrate change detector 126 can use the baseline thickness to determine whether the substrate has changed, for example, in thickness. For example, the frequency spectrum 124 for the transducer 104 can be computed (e.g., at some later time, after determining or receiving the baseline thickness for the substrate 102) in a same or similar manner, as disclosed herein. The frequency spectrum 124 can be processed by the substrate change detector 126 to determine the thickness of the substrate 102 in a same or similar manner, as disclosed herein. The determined thickness can be compared to the baseline thickness to detect a change in thickness of the substrate 102. For example, if the determined thickness is different from the baseline thickness, or has deviated by a given amount (e.g., by a value, a range, a percentage, etc.) this can be indicative of change in thickness. In some examples, the detected change in thickness of the substrate 102 can be provided as data and rendered on an output device 136.

In additional or alternative examples, the detected change (e.g., value) can be compared to a threshold by the change detector 126. If the detected change is greater than or equal to the threshold, an alert can be outputted on the output device 136 in response to the change detector 126. In some instances, the alert is outputted on the output device 136 in response to detecting the change in thickness of the substrate 102 by the change detector 126. For example, if the substrate 102 is part of a pipeline, the alert can indicate that the pipeline has reached an unacceptable level of corrosion, or has had a change in thickness that is not acceptable.

As the thickness of the substrate 102 decreases this causes a change in the resonance frequency and thus the thickness computed by the substrate change detector 126 based on the change in resonance frequency. As the resonance frequency increases, this indicates a decrease in thickness of the substrate. Although the substrate 102 was originally close in resonance frequency to the transducer 104 a small change in the resonance frequency of the substrate 102 can be detected If there is a strong frequency mismatch, for example, if the resonance frequency of the substrate 102 was about 0.107 MHz and the resonance frequency of the transducer 104 was about 1.0 MHz, such a large mismatch in resonance frequency would cause a splitting pattern in a frequency spectrum, which can also be caused by the appearance of peaks of higher harmonics of the resonance in the spectrum in the range of bandwidth of the transducer. By contrast, because the substrate 102 and the transducer 104 are resonance frequency matched, a small change in the resonance frequency of the substrate 102 may not result in the splitting pattern in the frequency spectrum 124, but rather a shift in the resonance frequency, thus allowing for accurate thickness detection by the change detector 126. For example, a small change in thickness in the substrate 102 can be manifested by a shift in a prominent peak of the resonance frequency.

In some examples, an additional layer 130 may form on the substrate 102. The additional layer 130 formed on the substrate 102 causes the resonance frequency of the substrate 102 to shift. For example, the additional layer 130 can be ice formed on the substrate 102. For example, if the substrate 102 is part of the pipeline that is located in a cold environment and temperatures permit ice formation on the substrate 102, the formed ice can cause the resonance frequency of the substrate 102 to shift. The additional layer 130 can cause resonance frequency shifting. In some examples, the additional layer 130 can be formed on at least a portion of the substrate 102 (e.g., from which the reflected sound wave is provided to the transducer 104).

In some examples, the substrate change detector 126 can detect the additional layer 130 on the substrate 102 in response to a frequency shift. A difference in frequency between the resonance frequency and the shifted resonance frequency can be attributed to the additional layer 130, and can be referred to as a frequency shift. The frequency shift, that is, an amount the resonance frequency shifts to a new resonance frequency for the substrate 102 can be based on a thickness of the additional layer 130. The substrate change detector 126 can determine that a frequency shift has occurred in response to determining that the resonance frequency (as specified by the resonance frequency data 128) has shifted to the new resonance frequency. In some examples, the substrate change detector 126 can compare the frequency shift to a frequency threshold and determine the resonance frequency has shifted to the new resonance frequency in response to determining that the frequency shift is greater or equal to the frequency threshold. The substrate change detector 126 can use the new resonance frequency (also can be referred to herein as a shifted resonance frequency) to compute a thickness representative of the thickness of the substrate 102 and the thickness of the additional layer 130 in a same or similar manner, as disclosed herein. The determined thickness of the substrate 102 with the additional layer 130 can be compared by the substrate change detector 126 to the baseline thickness and if the determined thickness is greater than the baseline thickness the substrate change detector 126 can determine that the additional layer 130 has been formed on the substrate 102. A difference between the determined thickness of the substrate 102 with the additional layer 130 and the baseline thickness can be indicative of the thickness of the additional layer 130.

In some examples, the substrate change detector 126 can provide data characterizing the thickness of the additional layer 130 for rendering on the output device 136. In additional or alternative examples, the thickness of the additional layer 130 can be compared to an additional layer thickness threshold by the change detector 126. If the thickness of the additional layer 130 is greater than or equal to the additional layer thickness threshold, an alert can be outputted on the output device 136 in response to the substrate change detector 126. In some instances, the alert is outputted on the output device 136 in response to the substrate change detector 126 detecting the additional layer 130. For example, if the additional layer 130 is ice, the alert provided on the output device 136 can indicate that ice has formed on the substrate (e.g., the pipeline).

In some examples, the system 100 can include a resonance frequency calculator 132. The resonance frequency calculator 132 can be used to determine (calculate) the resonance frequency of the substrate 102, as shown in FIG. 1. Thus, in some examples, the resonance frequency calculator 132 can be used to provide the resonance frequency of the substrate 102. In some examples, the resonance frequency calculator 132 can be used to determine the resonance frequency of the transducer 104. For example, the resonance frequency calculator 132 can use expression (1) to calculate the resonance frequency of the substrate 102 or the transducer 104:

$$f = \frac{c}{2 \times d} , \qquad ( 1 )$$

wherein f is the resonance frequency, c is the speed of sound, and d is a thickness of the substrate 102.

In some examples, the resonance frequency of the substrate 102 can change over time (e.g., due to corrosion and accumulation of ice). For example, initially, the transducer 104 can be frequency matched to the substrate 102 (e.g., in its original form). However, over time, the thickness of the substrate 102 can change, which results in a change in a resonance frequency of the substrate 102. As an example, if the substrate 102 is a pipe, over time, the thickness of the pipe will change due to corrosion. This change in resonance frequency can be detected according to one or more examples disclosed herein to correlate to either corrosion or accumulation of ice. In some examples, if the density of the substrate 102 changes, the resonance frequency would also change. The density can impact the speed of sound in the substrate 102, which would change the resonance frequency. In some examples, the density of the material 102 can change if, for example, corrosion caused pitting of the substrate 102. Because the transducer 104 is frequency matched to the substrate 102 (e.g., in its original condition, or upon transducer manufacturing) changes in resonance frequency of the substrate 102 would still result the substrates new resonance frequency to fall within a detectable frequency range of the transducer 104. In some examples, either modeling or experimentation can be used to indicate how a change in resonance frequency of the substrate 102 would shift or split an acoustic signature of the transducer 104 as the substrate 102 underwent a change (e.g., density or thickness change).

In some examples, the resonance frequency of the substrate 102 can be detected by the change detector 126 using expression (1) to calculate the thickness of the substrate. 102. A fundamental mechanical response occurs when the thickness of the piezoelectric material 106 is ½ wavelength thick. Thus, the resonance frequency occurs (and can be implemented by the calculator 132) according to expression (2):

$$d = \frac{1}{2} λ , \qquad ( 2 )$$

wherein λ is a wavelength of an acoustic wave (emitted by the transducer 104), and d is the thickness of the piezoelectric material 106.

Based on a relationship between the wavelength of the acoustic wave and the thickness of the piezoelectric material 106, the resonance frequency calculator 132 can compute the wavelength of the acoustic wave according to expression (3):

$$λ = 2 \times d . \qquad ( 3 )$$

The relationship between frequency and wavelength with respect to speed of sound for the substrate 102 can be computed according to expression (4):

$$c = f \times λ . \qquad ( 4 )$$

Thus, the resonance frequency of the substrate 102 can be calculated by the resonance frequency calculator 132 based on the speed of sound and the thickness of the substrate 102. For example, the resonance frequency calculator 132 can receive substrate data 134 characterizing the speed of sound and the thickness of the substrate 102 for calculating the resonance frequency of the substrate 102. In some examples, the speed of sound through the substrate 102 can be calculated (or determined) according to expression (5):

$$c = \frac{2 d}{Δ T} , \qquad ( 5 )$$

wherein c is the speed of sound, d is the thickness of the substrate 102, and ΔT is a difference in time between echoes (directed at the substrate 102), and can be obtained from a time domain spectrum for the substrate 102.

In some examples, the computed resonance frequency of the substrate 102 can be provided by the calculator 132 to an output device 136. The output device 136 can render the result. The computed resonance frequency of the substrate 102 can be used for example, during fabrication, for tuning the thickness of the piezoelectric material 106 so that the resonance frequency of the transducer 104 matches the computed resonance frequency of the substrate 102.

Accordingly, matching the resonance frequency of the transducer 104 to the substrate 102 prevents frequency interference from the substrate 102 with the transducer frequency and thus creating complex splitting patterns in the frequency domain (in the frequency spectrum 124), which can also be caused by higher harmonics. Resonance frequency matching allows for a simplified ultrasound in both the time domain and the frequency domain. Because the resonance frequency of the substrate 102 is considered according to one or more examples disclosed herein, the characteristics (e.g., the resonance frequency) of the substrate 102 can be incorporated during transducer manufacturing. As disclosed herein, in some instances the transducer 104 is produced with a composite piezoelectric material(s) (corresponding to the piezoelectric material 106), and the thickness of the composite piezoelectric material can be tuned to cause the fabricated transducer 104 to match the frequency of the substrate 102. Because the transducer 104 with the composite piezoelectric material has a broader bandwidth than a dense ceramic piezo-transducer, the transducer 104 is more sensitive to detecting frequency changes as the transducer's bandwidth is greater. The bandwidth of the composite piezoelectric material can be tuned during a process of creating or constructing the transducer 104, for example, by changing a shape of the piezoelectric material, printing parameters, or adding/modifying a backing layer of the transducer 104.

In some examples, the transducer 104 can be manufactured with a backing layer and/or an acoustic impedance matching layer. The backing layer can sit on one side of the electrodes between which the piezoelectric material 106 is located. The backing layer can be added to dampen the electrical signal 114 provided by the transducer 104 (generated by the piezoelectric material 106). The addition of the backing layer can reduce the ringing of the piezo, which can be desirable for higher resolution transducers, as well as broaden the resonance frequency, thereby improving a sensitivity of the transducer 104. The backing layer and the acoustic impedance matching layer can be incorporated during manufacturing of the transducer 104 to improve a quality of acoustic signals by i) reducing interfering acoustic signals by absorbing and scattering sound waves off the backing layer, and ii) improving an acoustic energy transfer into layers of interest, thereby increasing signal-to-noise (SNR) of received acoustic signals (using the acoustic impedance matching layer). Thus, the acoustic impedance matching layer can improve transfer of acoustic energy generated by the transducer 104 into an adjacent layer (e.g., the substrate 102).

FIG. 2 is an example of a transducer 202 emitting a sound wave 204 at a number of materials 206-208, identified as “M1” and “M2,” respectively. The transducer 202 includes electrodes 210-212 between which a piezoelectric material 214, for example, the piezoelectric material 106, as shown in FIG. 1. Thus, reference can be made to one or more examples of FIG. 1 in the example of FIG. 2. In some examples, the transducer 202 corresponds to the transducer 104, as shown in FIG. 1. For clarity and brevity purposes not all layers/features of the transducer 104/202 are shown in the example of FIGS. 1-2. A voltage (e.g., the input voltage 112, as shown in FIG. 1) can be applied to the electrodes 210-212 to cause the piezoelectric material 214 to emit the sound wave 204. The sound wave 204 propagates through the materials 206-208 and each of the materials 206-208 reflect the sound wave 204 as reflected sound waves 216-218, respectively. For example, an interface of the materials 206-208 can reflect a portion of the sound wave 204 to provide one of the reflected sound waves 216-218. The reflected sound waves 216-218 can be provided by the transducer 202 as electrical signals to the acoustic wave analysis system 100 for processing according to one or more examples disclosed herein. In some examples, the material 208 can be the additional layer 130 and the material 206 can be the substrate 102, as shown in FIG. 1. The system 100 can process the electrical signal (representative of the reflected sound waves 216-218) to determine whether the thickness of the material 206 has changed, and in some instances detect the material 208, once formed on the material 206 (substrate).

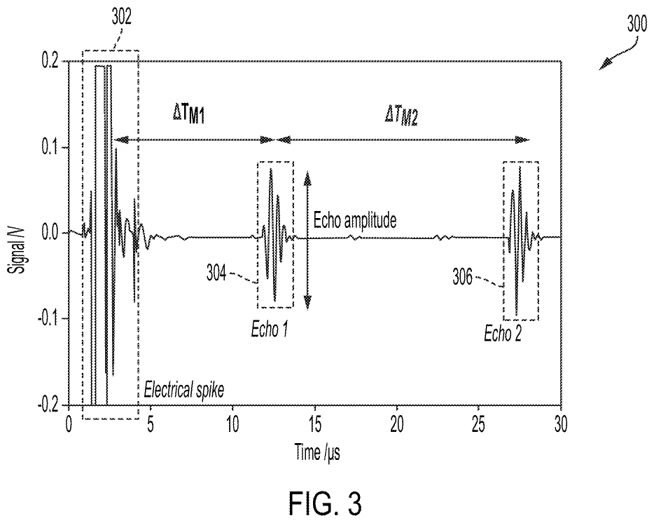

FIG. 3 is an example of a graph 300 of acoustic pulses emitted and captured by a transducer, for example, as disclosed herein. Thus, reference can be made to one or more examples of FIGS. 1-2 in the example of FIG. 3. The graph 300 includes an emitted acoustic pulse (sound wave) 302, and captured acoustic pulses (reflected sound waves) 304-306. For example, a distance traveled by the emitted acoustic pulse can be calculated (e.g.,, by the acoustic wave analysis system 100, as shown in FIG. 1) according to the following expression:

$$D = \frac{Δ T \times c}{2} , \qquad ( 5 )$$

wherein D is the distance traveled, ΔT is a difference in time between pulses/echoes, and c is the speed of sound.

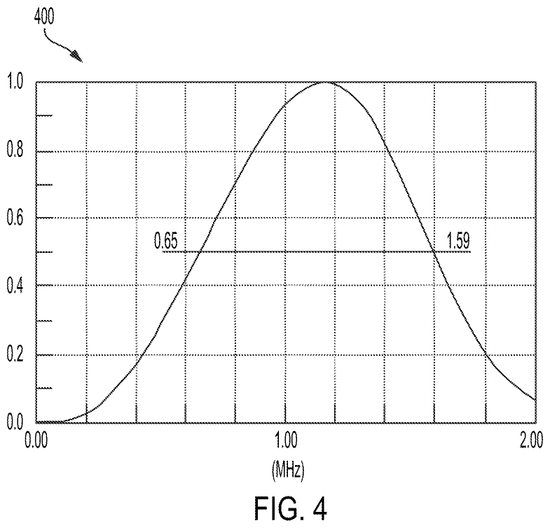

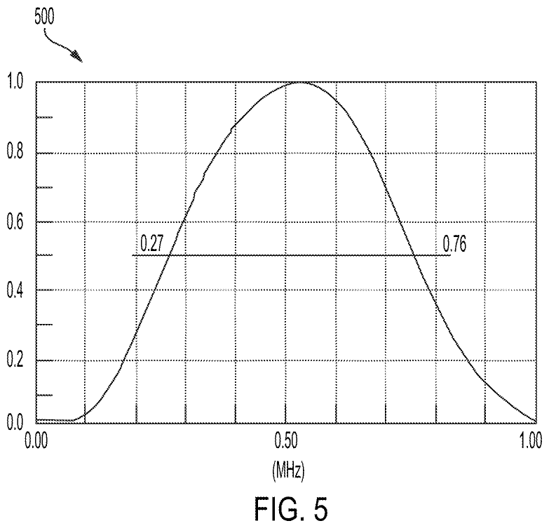

FIGS. 4-5 are examples of graphs 400-500 of a frequency spectrum of a resonance frequency of respective transducers having different resonance frequencies, for example, of about 1 Megahertz (MHz) and 0.5 MHz.

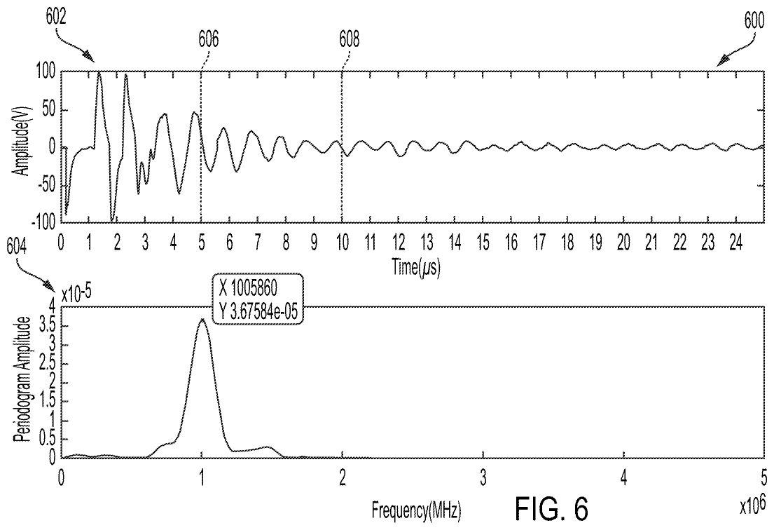

FIG. 6 is an example of acoustic signature graphs 600 acquired using a 1 MHz transducer. The graphs 600 includes an acoustic signature graph 602 with an electrical signal obtained by applying the 1 MHz transducer against a 3.22 millimeter (mm) aluminum substrate (using a coupling gel) at a room temperature having the resonance frequency, as shown in FIG. 4, and a frequency spectrum response graph 604 based on the electrical signal. The aluminum substrate with the thickness 3.22 mm can resonate at a frequency of about 1 MHz. In the example of FIG. 6, clamps 606-608 can be used to identify or select a portion (region) of the electrical signal in the graph 602 used for providing the frequency spectrum response graph 604.

The selected region between the clamps 606-608 in the plot 602 is the data that is transformed into the data displayed in the frequency domain in the plot 604. Criteria can be followed for conversion to the frequency domain of the data selected by the clamps 606-608. It is beneficial to be away from the excitation signal so that only the frequencies generated as the response of the substrate will be in the frequency domain spectrum. For this reason, 5 μs can be selected as the beginning of the region of interest by the clamp 606. The acoustic signal is attenuated over time (for a variety of reasons, material composition, material integrity, etc.), therefore a signal-to-noise ratio (SNR) decreases over time, at which point, the noise becomes a contributing component in the spectrum. For this reason, 10 μs was selected as the end of the region of interest by the clamp 608, to eliminate as much as possible the contribution of noise to the spectrum. The chart 604 shows a resulting prominent peak in the frequency domain around 1 MHz. The smaller peaks in the chart 604 in the base of the frequency domain peak can be the result of noise and/or the result of acoustic shear waves.

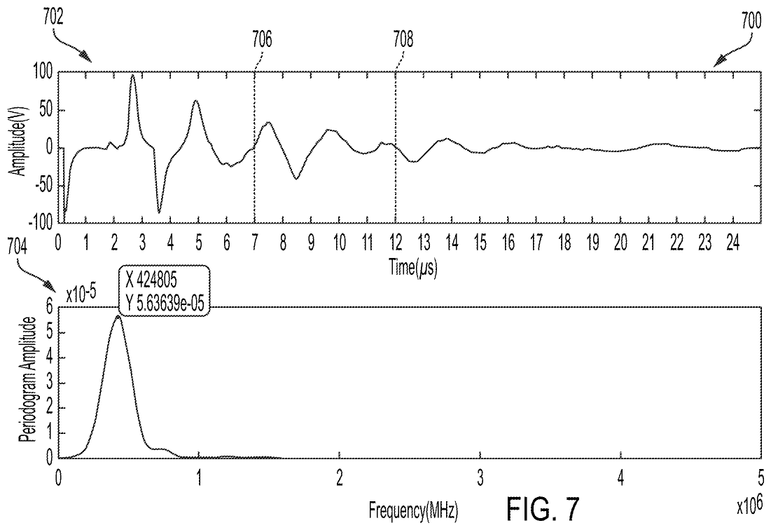

FIG. 7 is an example of acoustic signature graphs 700 acquired using a 0.5 MHz transducer. The graphs 700 includes an acoustic signature graph 702 with an electrical signal obtained by applying the 0.5 MHz transducer against a 6.35 mm aluminum substrate (using a coupling gel) at a room temperature having the resonance frequency, as shown in FIG. 5, and a frequency spectrum response graph 704 based on the electrical signal. The aluminum substrate with the thickness 6.35 mm can resonate at a frequency of about 0.5 MHz and thus has a prominent peak. In the example of FIG. 7, clamps 706-708 can be used to identify or select a portion (region) of the electrical signal in the graph 702 used for providing the frequency spectrum response graph 704.

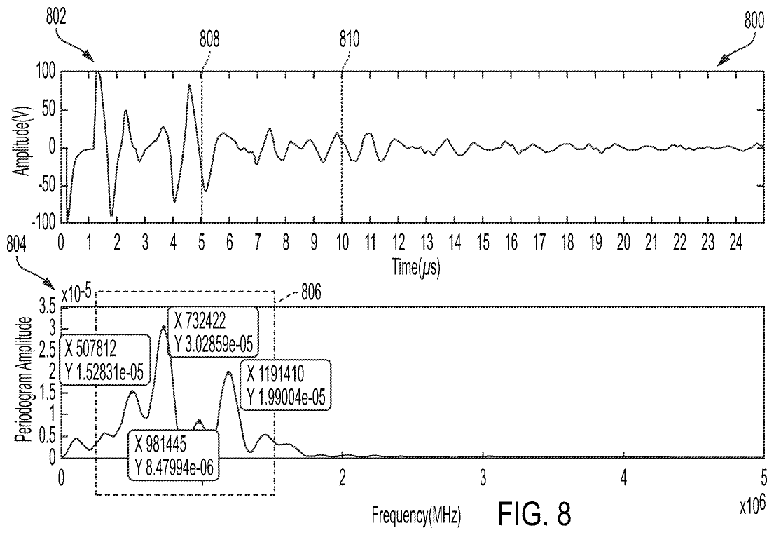

FIG. 8 is an example of acoustic signature graphs 800 acquired using a 1.0 MHz transducer. The graphs 800 includes an acoustic signature graph 802 with an electrical signal obtained by applying the 1 MHz transducer against a 9.58 mm aluminum substrate (using a coupling gel) at room temperature having the resonance frequency, as shown in FIG. 5, and a frequency spectrum response graph 804 based on the electrical signal. The aluminum substrate with the thickness 9.58 mm can resonate at a frequency of about 0.335 MHz and thus results in a complex frequency pattern 806, as shown in FIG. 8. In the example of FIG. 8, clamps 808-810 can be used to identify or select a portion (region) of the electrical signal in the graph 702 used for providing the frequency spectrum response graph 704. Because the substrate resonance and the transducer resonance are not the same (in contrast to the examples of FIGS. 6-7), there is a complex pattern in the frequency domain resulting from the destructive interference of the two resonance frequencies (the resonance frequencies of the transducer and the substrate). In the example of FIG. 8, the complex frequency pattern 806 includes a number of frequency peaks (dominant frequency peaks), making it difficult to know which peak (e.g., a prominent peak) should be used for processing (e.g., by the system 100, as shown in FIG. 1), or distinguishing peaks if the splitting becomes more complex with additional layers, according to one or more examples disclosed herein.

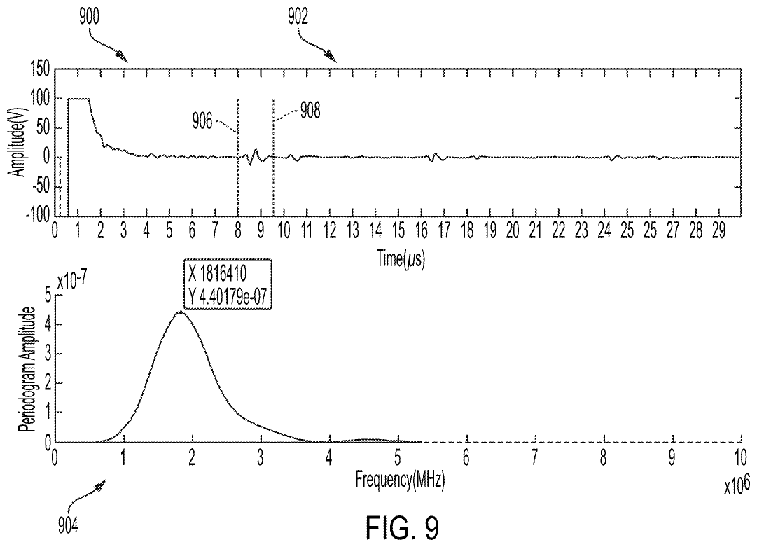

FIG. 9 is an example of acoustic signature graphs 900 acquired using a transducer that is about 0.5 mm thick and with a resonance frequency of about 1.817 MHz. The transducer can include a piezoelectric composite material. The advantage of using piezoelectric composite materials for construction of the transducer is that the thickness can be tuned by 3D printing, or molding, or pressing, therefore allowing for matching the resonance frequencies of different substrates by the transducer. In an example, the piezoelectric composite material includes Elvamide 8064 (polyamide) with 50 vol % PZT-NH₂ and 2 wt % Nexamite A32 and 8 wt % Nexamite A33. Elvamide 8064 is a Dupont copolymer of polyamide (PA6/66/610 copolymer) that has a Tm=156° C. Nexamite A32 and Nexamite A33 are a polyamide alkynyl-based cross-linking system from Nexam chemical.

For example, the transducer can be prepared by heat pressing the piezoelectric composite material followed by cross-linking the material at 200° C. for about 48 hours. A conductive epoxy can be added as an electrode. The transducer can be poled using about 5 kV to generate a corona, with a distance of about 2.5 mm between the corona source and transducer, and heating the sample to about 100° C. for about 1.5 hours. The piezo composite material has a thickness of about 0.5 mm and an epoxy electrode backing layer has a thickness of about 1.3 mm. The conductive epoxy backing layer is 8331D—Silver Conductive Epoxy Adhesive from MGChemicals. The d33 (piezoelectric coefficient or piezoelectric modulus) of the transducer was about 8 pC/N. For this composite material, the speed of sound can be determined to be 1817 m/s. Using expression (1), as disclosed herein, the expected resonance frequency for the transducer that is 0.5 mm thick is about 1.817 MHz.

Continuing with the example of FIG. 9, the graphs 900 includes an acoustic signature graph 902 with an electrical signal obtained by applying the 1.817 MHz transducer against a 25.33 mm aluminum substrate and a frequency spectrum response graph 904 based on the electrical signal. In the example of FIG. 9, clamps 906-908 can be used to identify or select a portion (region) of the electrical signal in the graph 902 used for providing the frequency spectrum response graph 904. FIG. 9 shows acoustic data collected using the transducer on the 25.3 mm aluminum substrate. The transducer produces clear echoes that correlate with the thickness of the aluminum substrate. FFT transformation of a single echo in the time domain provides the resonance frequency of the transducer, seen in the frequency domain, the graph 904.

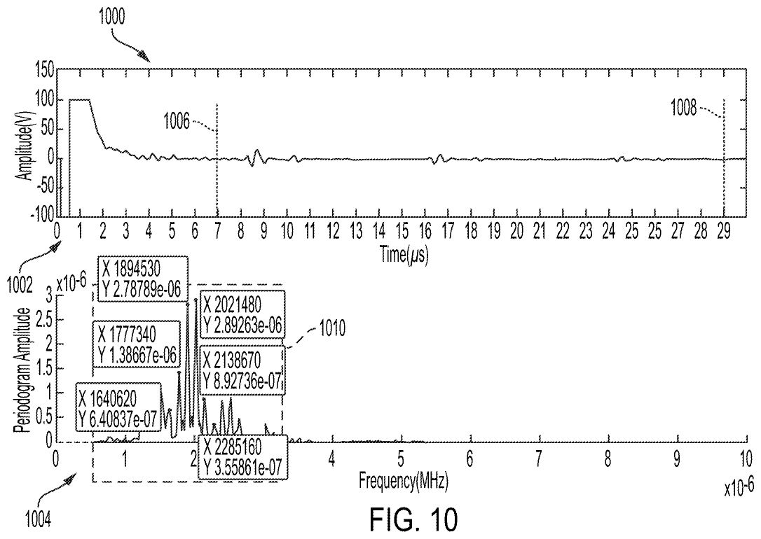

If multiple echoes in the time domain are selected for FFT transformation into the frequency domain, the interference pattern of the substrate frequency with the transducer resonance frequency can create a complex pattern 1010, as shown in FIG. 10. FIG. 10 shows the resulting pattern of the resonating frequencies of the 25.3 mm aluminum substrate (0.127 MHz) acquired using the 1.817 MHz transducer. FIG. 10 includes graphs 1000 includes an acoustic signature graph 1002 with an electrical signal obtained by applying the 1.817 MHz transducer against the 25.33 mm aluminum substrate, and a frequency spectrum response graph 1002 based on the electrical signal. The aluminum substrate with the thickness 25.33 mm can resonate at a frequency of about 0.127 MHz. In the example of FIG. 10, clamps 1006-1008 can be used to identify or select a portion (region) of the electrical signal in the graph 1002 used for providing the frequency spectrum response graph 1004. Thus, selection of a larger range with multiple echoes in the time domain results in the complex splitting pattern 1010 of the resonance frequencies of the substrate and transducer in the frequency domain.

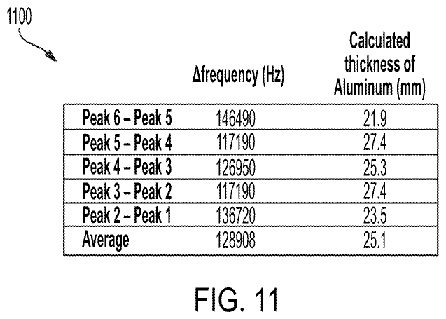

The resonance frequency of the 25.3 mm aluminum substrate can be verified by subtracting the differences between the peaks in the frequency domain 1010, as shown in the graph 1004. FIG. 11 illustrates a table 1100 with calculated frequency and corresponding calculated thickness of the aluminum substrate. The calculated resonance frequency and thickness for the 25.3 mm aluminum substrate (0.127 MHz) and the observed average resonance frequency (0.129 MHz) are about the same (or match).

Addition of layers to the substrate under test (for example, ice) can create a more complex pattern in the frequency domain that would make it more difficult to analyze. However, in implementations in which the frequency of the transducer and substrate are matched, would result in a prominent peak in the frequency domain from both the transducer and the substrate, and thus make analysis of changes to the substrate easier and more accurate to detect.

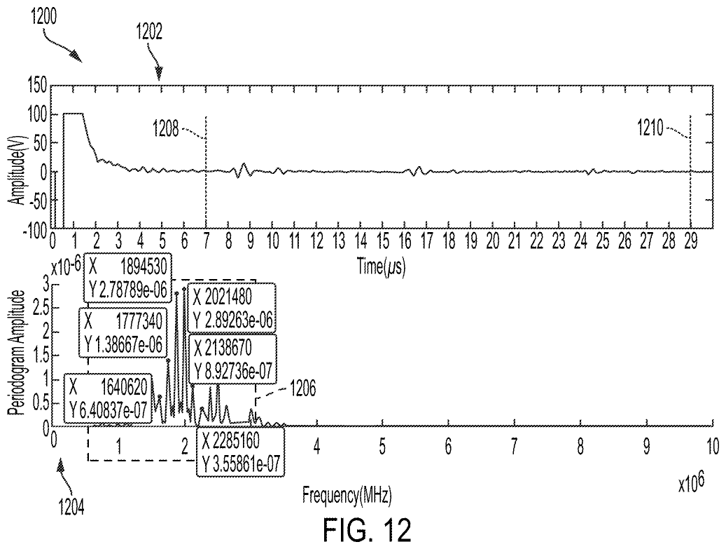

In some examples, the transducer resonates at about 1.817 MHz. An aluminum substrate with thickness of about 1.65 mm thickness can resonate at a frequency of about 1.945 MHz. FIG. 12 is an example of acoustic signature graphs 1200 acquired using a 1.187 MHz transducer. The graphs 1200 includes an acoustic signature graph 1202 with an electrical signal obtained by applying the 1.817 MHz transducer against a 25.3 mm aluminum substrate, and a frequency spectrum response graph 1204 based on the electrical signal. A complex frequency pattern 1206, as shown in FIG. 12 results due to a resonance frequency mismatch of the 1.817 MHz transducer and the 25.33 mm aluminum substrate resonating at about 0.127 MHz. In the example of FIG. 12, clamps 1208-1210 can be used to identify or select a portion (region) of the electrical signal in the graph 1202 used for providing the frequency spectrum response graph 1204.

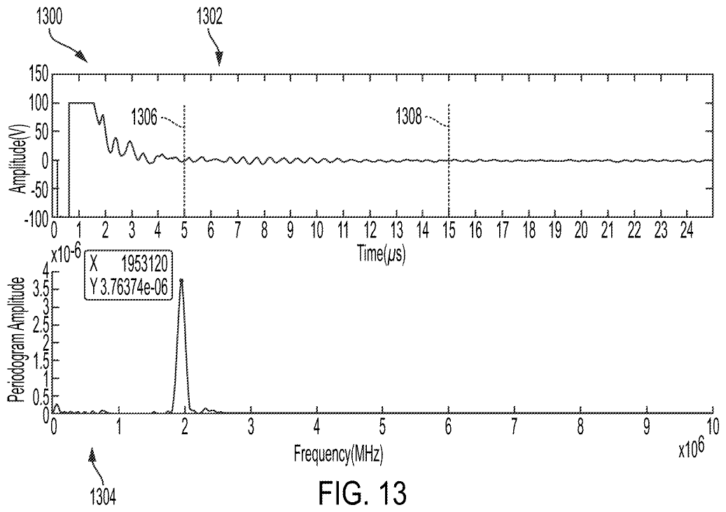

FIG. 13 is an example of another acoustic signature graphs 1300 acquired using a 1.187 MHz transducer. The graphs 1300 includes an acoustic signature graph 1302 with an electrical signal obtained by applying the 1.817 MHz transducer against a 1.65 mm aluminum substrate, and a frequency spectrum response graph 1304 based on the electrical signal. As shown in FIG. 13, a prominent peak results (no complex frequency pattern as in the example of FIG. 12) due to a resonance frequency of the 1.817 MHz transducer being about the resonance frequency of the 1.65 mm aluminum substrate. In the example of FIG. 13, clamps 1306-1308 can be used to identify or select a portion (region) of the electrical signal in the graph 1302 used for providing the frequency spectrum response graph 1304.

Accordingly, when the resonance frequencies are mismatched, a complex splitting pattern is observed in the frequency domain and when the frequencies are matched, a prominent peak is observed in the frequency domain. The system 100, as disclosed herein, can determine whether there is a prominent frequency in a frequency range associated with the substrate and if the prominent frequency is not present in the frequency range, and/or if the prominent frequency has an amplitude that is less than a given threshold or has shifted, which can be indicative of a change in the substrate (e.g., change in thickness). This is because as the thickness of the substrate changes its resonance frequency shifts away from the resonance frequency of the transducer having a resonance frequency similar to the substrate. This shift resonance frequency can be used as an indication of substrate thickness change. For example, if the substrate is a metal and is experiencing corrosion, the substrate will have a shifted resonance frequency that can be detected by the system 100. An alert can be generated to notify personnel (or user) of the corrosion of the metal.

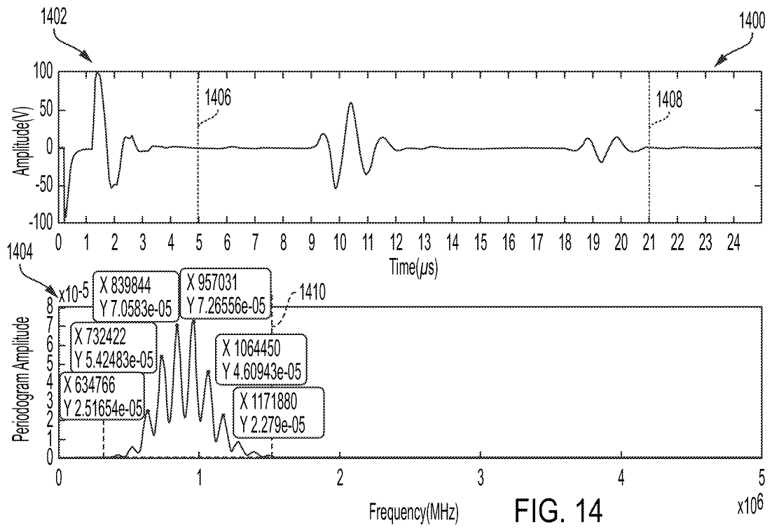

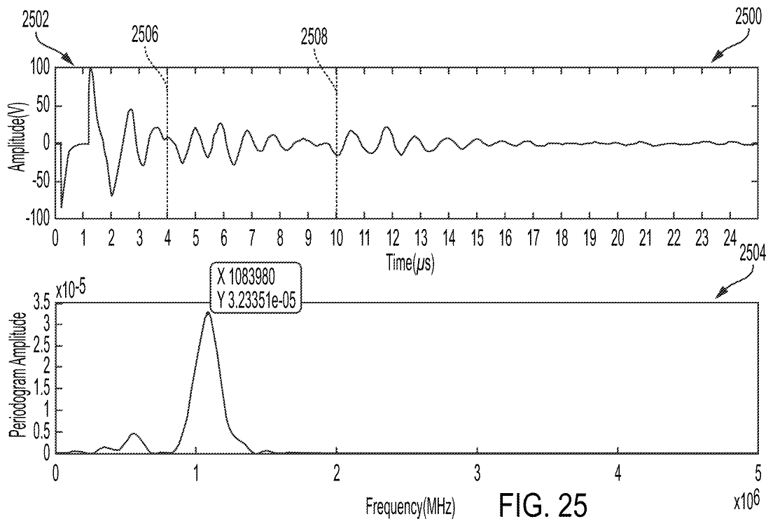

In some examples, a resonance frequency peak of the substrate can change (e.g., due to a change in substrate thickness), or shift, for example, in the presence of an additional layer on the substrate, a carbon fiber reinforced polymer (CFRP), and/or ice. FIGS. 14-24 relate to a first example (or examples), illustrating changes (shifts) in resonance frequency peaks due to the presence of an additional material that is not ice. FIGS. 25-33 relating to a second example (or examples) illustrating how the resonance frequency of the transducer and the substrate shift in the presence of the ice (as the additional layer) on the substrate.

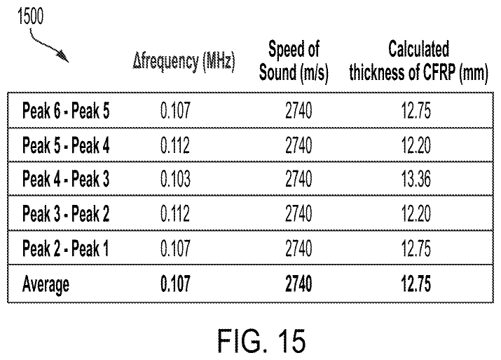

For example, FIG. 14 is an example of graphs 1400 acquired using a 1 MHz transducer (probe). The graphs 1400 includes an acoustic signature graph 1402 with an electrical signal obtained by applying the 1 MHz transducer against a 12.84 mm CFRP, and a frequency spectrum response graph 1404 based on the electrical signal. In the example of FIG. 14, clamps 1406-1408 can be used to identify or select a portion (region) of the electrical signal in the graph 1402 used for providing the frequency spectrum response graph 1404. The layer can include a 12.84 mm CFRP. In the example of FIG. 14, the 1 MHz probe is in contact with the 12.84 mm CFRP. Because the 12.84 mm CFRP and the 1 MHz transducer are frequency mismatched, a splitting pattern 1410 is observed in the frequency domain (the graph 1404) from the 1 MHz probe on the 12.84 mm CFRP. The CFRP can resonate at about 0.107 MHz. This is verified by subtracting the dominant peaks in the frequency domain, as shown in table 1500. FIG. 15 illustrates a table 1500 with calculated frequency from the frequency domain splitting pattern and corresponding calculated thickness of the CFRP (in mm) using expression (1), as disclosed herein.

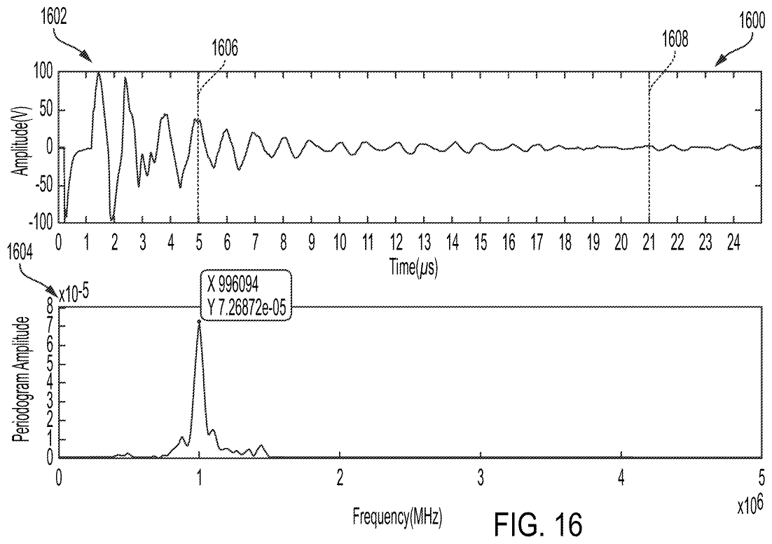

FIG. 16 is an example of graphs 1600 acquired using a 1 MHz transducer. The graphs 1600 includes an acoustic signature graph 1602 with an electrical signal obtained by applying the 1 MHz transducer against the 3.20 mm aluminum substrate, and a frequency spectrum response graph 1604 based on the electrical signal. In the example of FIG. 16, clamps 1606-1608 can be used to identify or select a portion (region) of the electrical signal in the graph 1602 used for providing the frequency spectrum response graph 1604. The graph 1604 (in contrast to the graph 1404 of FIG. 14) has no complex pattern and a single peak (a prominent peak) is observed in the frequency domain at about 1 MHz. This is because the resonance frequency of the 1 MHZ transducer overlaps with the resonance frequency of the 3.20 mm aluminum substrate eliminating the dominant peaks as shown in FIG. 14.

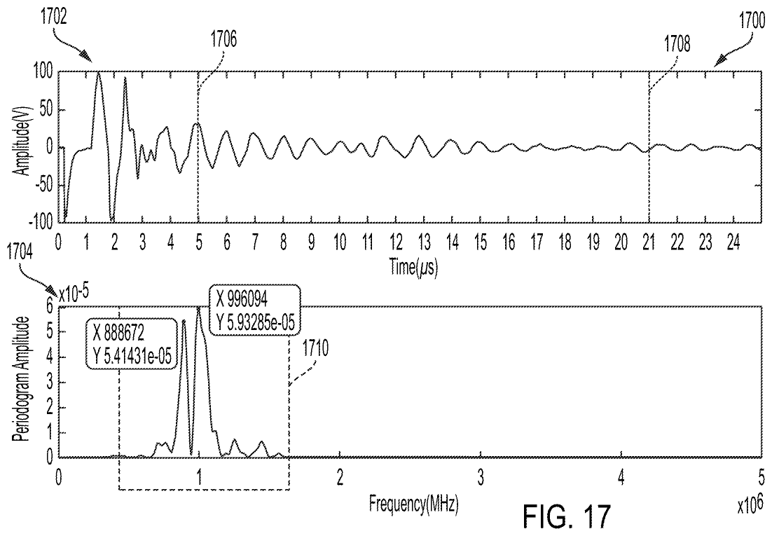

FIG. 17 is an example of graphs 1700 for about 1 MHz transducer. The graphs 1700 includes an acoustic signature graph 1702 with an electrical signal obtained by applying the 1 MHz transducer against the two (2) layers, and a frequency spectrum response graph 1704 based on the electrical signal. In the example of FIG. 17, clamps 1706-1708 can be used to identify or select a portion (region) of the electrical signal in the graph 1702 used for providing the frequency spectrum response graph 1704. In the example of FIG. 17, the 1 MHz probe is in contact with the 3.20 mm aluminum substrate, which is in contact with the 12.84 mm CFRP. The 1 MHz probe in contact with a first layer of 3.20 mm aluminum with a resonance frequency that is about the resonance frequency of the probe, produces a prominent peak as is rendered in FIG. 16 pattern 1604. The addition of the second layer of 12.84 mm CFRP produces split dominant peaks, resulting in the pattern 1710 of the graph 1704, as shown in FIG. 17. The pattern 1710 is the result of the interference pattern of the resonance frequency of CFRP (frequency=0.107 MHz) with the resonance frequencies of the transducer and the 3.20 mm aluminum (1 MHz).

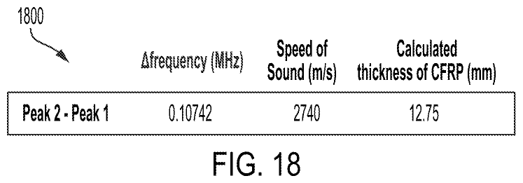

Subtracting the frequencies of the peaks in the frequency domain can be used to verify the resonance frequency of the CFRP of 0.107 MHz, and using the speed of sound of CFRP can be used to verify the thickness of the CFRP as 12.75 mm (rounded to 12.8 mm) according to one or more expressions as disclosed herein. FIG. 18 illustrates a table 1800 with a calculated frequency and corresponding calculated thickness of the CFRP (in mm).

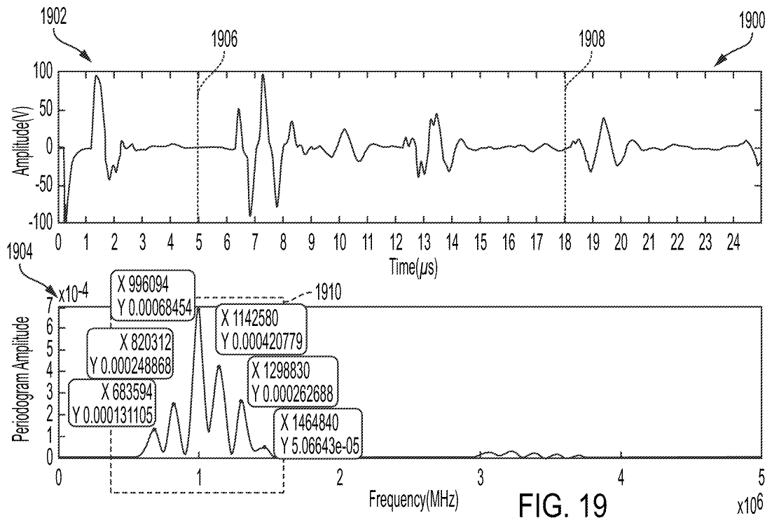

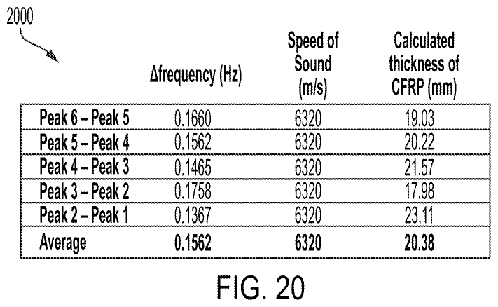

FIG. 19 illustrates an example of graphs 1900 acquired using a 1 MHz transducer in which the first substrate is not frequency matched with the transducer. The graphs 1900 includes an acoustic signature graph 1902 with an electrical signal obtained by applying the 1 MHz transducer against a mismatched layer, and a frequency spectrum response graph 1904 based on the electrical signal. In the example of FIG. 19, clamps 1906-1908 can be used to identify or select a portion (region) of the electrical signal in the graph 1902 used for providing the frequency spectrum response graph 1904. In the example of FIG. 19, the 1 MHz probe is on a 19 mm aluminum substrate. Because the transducer has a different resonance frequency than the 19 mm aluminum substrate, a splitting pattern 1910 is observed in the frequency domain (the graph 1904) from the 1 MHz probe on the 19.0 mm aluminum substrate. FIG. 20 illustrates a table 2000 with calculated frequencies and corresponding calculated thicknesses of the aluminum (in mm) with respect to the example of FIG. 19.

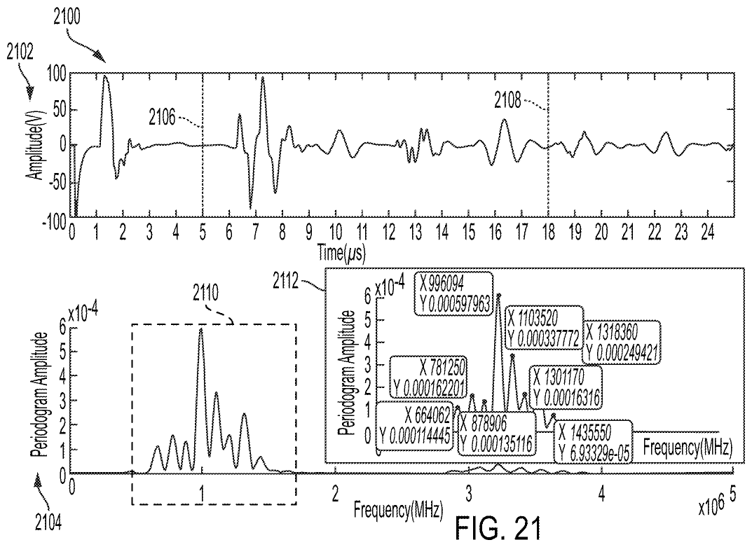

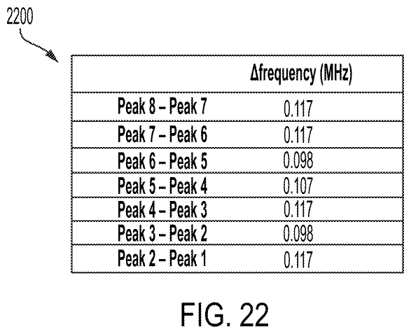

FIG. 21 illustrates an example of graphs 2100 acquired using a 1 MHz transducer in which the first substrate is not frequency matched with the transducer and on a second layer, such as the 12.84 mm CFRP, which is not frequency matched with the transducer. The graphs 2100 includes an acoustic signature graph 2102 with an electrical signal obtained by applying the 1 MHz transducer against a first layer of two layers, and a frequency spectrum response graph 2104 based on the electrical signal. In the example of FIG. 21, clamps 2106-2108 can be used to identify or select a portion (region) of the electrical signal in the graph 2102 used for providing the frequency spectrum response graph 2104. In the example of FIG. 21, the 1 MHz probe is on the 19 mm aluminum substrate (the first layer), which is on the 12.84 mm CFRP (the second layer). Because the transducer has a different resonance frequency than the 19 mm aluminum substrate and a different resonance frequency than the 12.84 mm CFRP, a splitting pattern 2110 (more complex in contrast to FIG. 19) is observed in the frequency domain (the graph 2104) from the 1 MHz probe on the 19.0 mm aluminum substrate. FIG. 22 illustrates a table 2200 with calculated frequencies for peaks with respect to the example of FIG. 21.

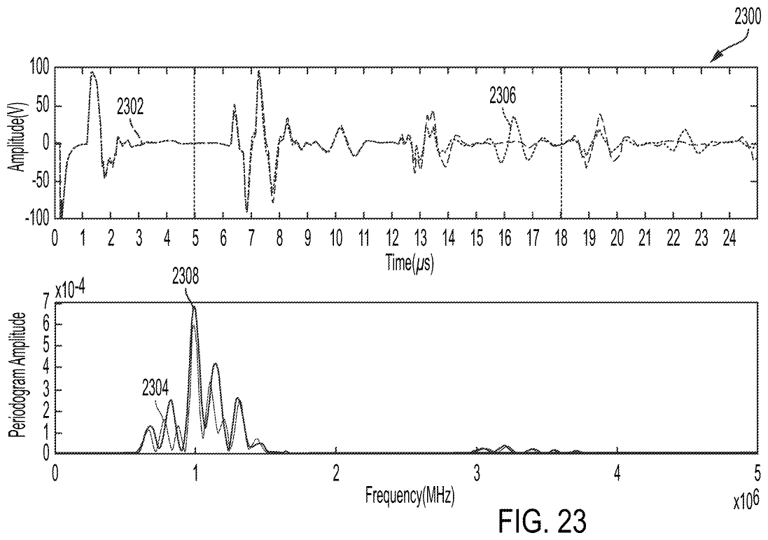

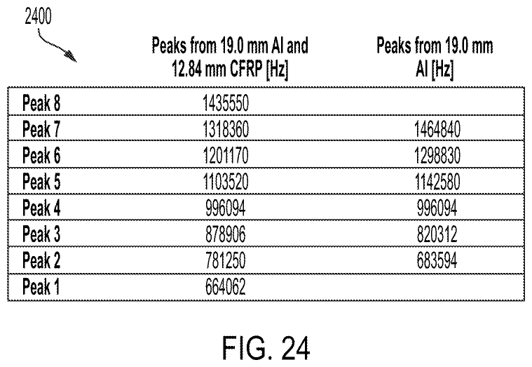

The dominant peaks produced in the frequency domain from the 19.0 mm aluminum and 12.84 mm CFRP with respect to FIGS. 21-22 is a complex pattern of overlapping acoustic waves from the reflections at the two interfaces as well as other combinations of reflections. FIG. 23 is an example of graphs with signals and frequency spectrum overlaid from the example of FIGS. 19 and 21. Thus, FIG. 23 is an overlay of data from the 1 MHz transducer with the 19.0 mm aluminum substrate (identified with reference numerals 2302-2304) and the 1 MHz transducer with the 19.00 mm aluminum substrate (identified with reference numerals 2306-2308) which is on or in contact with the 12.84 mm CFRP. The overlay highlights the difference between the two examples. As illustrated by the example of FIG. 23, the difference between dominant peak positions/changes is significant. FIG. 24 illustrates a table 2400 with calculated frequencies for peaks (from left to right) with respect to the example of FIG. 23.

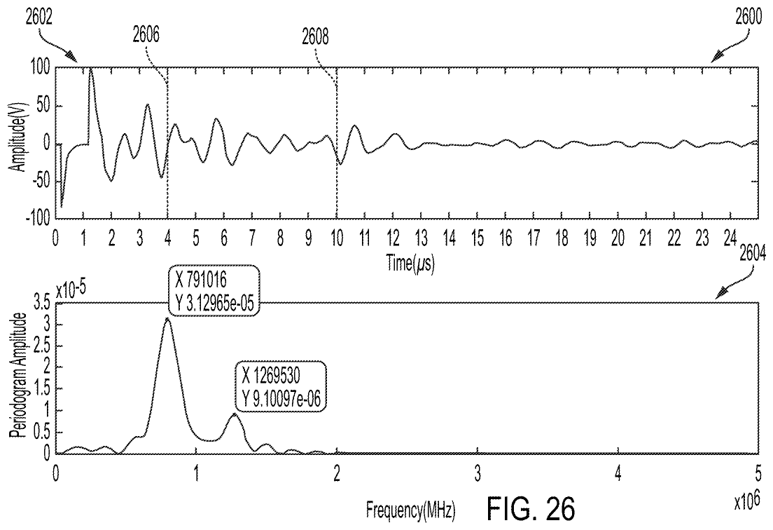

In some examples, for example, the second example, the resonance frequency of the transducer and aluminum substrate shifts with the additional layer of ice, as shown in FIGS. 25-33. FIGS. 25-23 show a resulting time domain and frequency domain obtained using a 1 MHz transducer with a 3.22 mm aluminum plate without ice and with different thicknesses of ice at −10° C. FIG. 25 illustrates graphs 2500 obtained using a 1 MHz transducer. The graphs 2500 include an acoustic signature graph 2502 with an electrical signal obtained by applying the 1 MHz transducer against the 3.22 mm aluminum substrate without a layer of ice, and a frequency spectrum response graph 2504 based on the electrical signal. In the example of FIG. 25, clamps 2506-2508 can be used to identify or select a portion (region) of the electrical signal in the graph 2502 used for providing the frequency spectrum response graph 2504. A similar clamp range is used with respect to FIGS. 26-29. In some examples, the graphs 2500 can be referred to as baseline graphs.

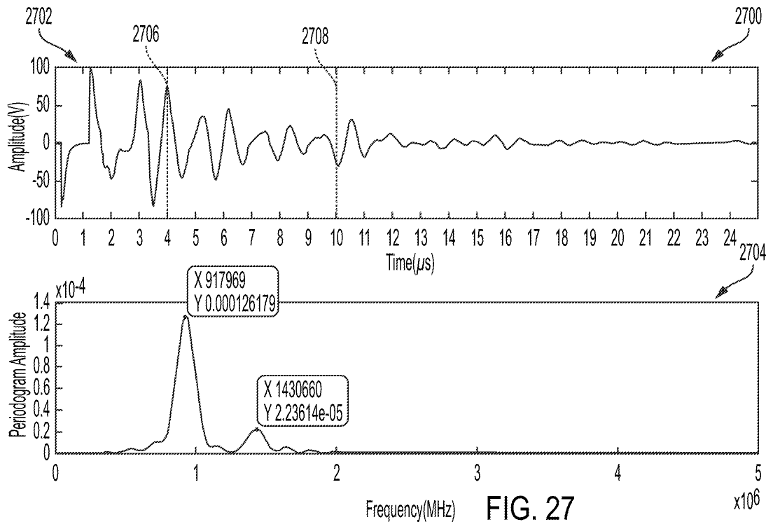

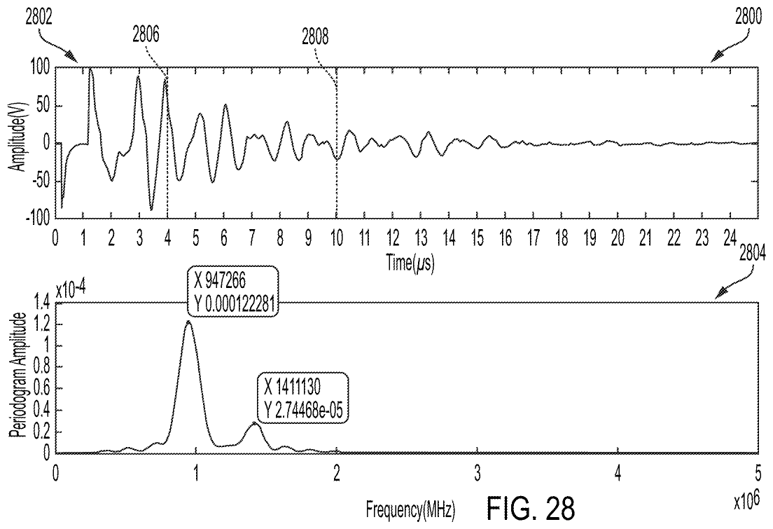

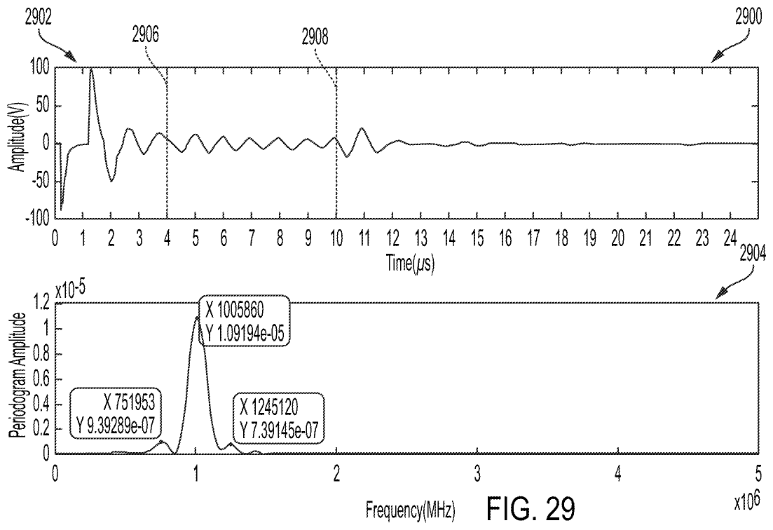

FIG. 26 illustrates graphs 2600 acquired using a 1 MHz transducer with ice. The graphs 2600 include an acoustic signature graph 2602 with an electrical signal obtained by applying the 1 MHz transducer against the 3.22 mm aluminum substrate with a layer of ice about 1 mm thick, and a frequency spectrum response graph 2604 based on the electrical signal. FIG. 27 illustrates graphs 2700 acquired using a 1 MHz transducer with less ice in connection with the example of FIG. 26. The graphs 2700 include an acoustic signature graph 2702 with an electrical signal obtained by applying the 1 MHz transducer against the 3.22 mm aluminum substrate with a layer of ice that is less than 1 mm thick (e.g., following removal of some ice by scraping from the 3.22 mm aluminum substrate), and a frequency spectrum response graph 2704 based on the electrical signal. FIG. 28 illustrates graphs 2800 acquired using a 1 MHz transducer following some additional ice removal. The graphs 2800 include an acoustic signature graph 2802 with an electrical signal obtained by applying the 1 MHz transducer against the 3.22 mm aluminum substrate with a layer of ice that is less thick than the ice used for providing the graphs 2700 (e.g., following removal of additional ice by scraping from the 3.22 mm aluminum substrate), and a frequency spectrum response graph 2804 based on the electrical signal. FIG. 29 illustrates graphs 2900 acquired using a 1 MHz transducer following complete removal of ice to regenerate the baseline graphs, for example, as shown in FIG. 26.

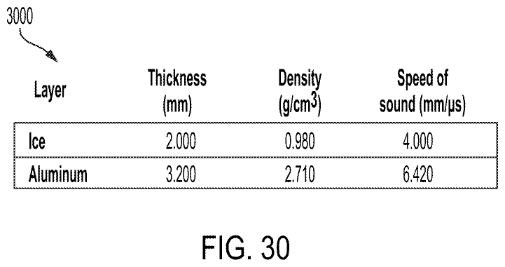

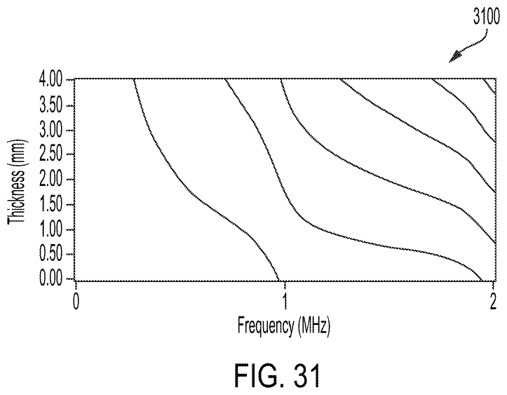

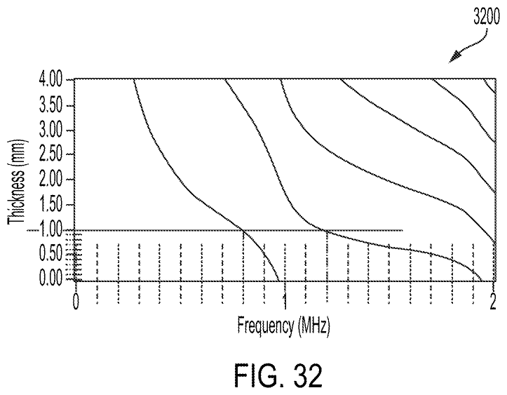

In some examples, the observed shifts in the resonance frequency peak can be validated by comparing these shifts to the shift in peaks predicted by a frequency-thickness model. The frequency-thickness model can include a calculated relationship between a thickness of an additional layer (e.g., of ice) with shifts in a resonance frequency of a piezoelectric transducer, for example, as disclosed herein. The frequency-thickness model can process a thickness of each layer (e.g., substrate and the additional layer, for example, accreting material), a density of each material for each layer, and a speed of sound of each layer. The frequency-thickness model, in some instances, can be used to verify observed shifts in the resonance frequency with known thicknesses. In an example, a two-layer system that includes an aluminum substrate as a bottom layer and ice as a top layer (e.g., a top accreting layer). FIG. 30 illustrates a table 3000 with parameters used for modeling, as disclosed herein, for predicting frequencies that can be observed in a frequency domain under given conditions. Thus, the table 3000 summarizes the parameters used for modeling to provide a frequency-thickness graph, for example, as shown in FIG. 31. In the example of FIGS. 31-32, the x-axis represents a frequency in MHz, and a y-axis represents a thickness in mm. As FIG. 31 illustrates, the resonance frequency shifts with changes in thickness of the additional layer (e.g., the ice layer) consistent with the resonance frequency shifts of the 1 MH transducer, for example, as described with respect to FIGS. 26-29.

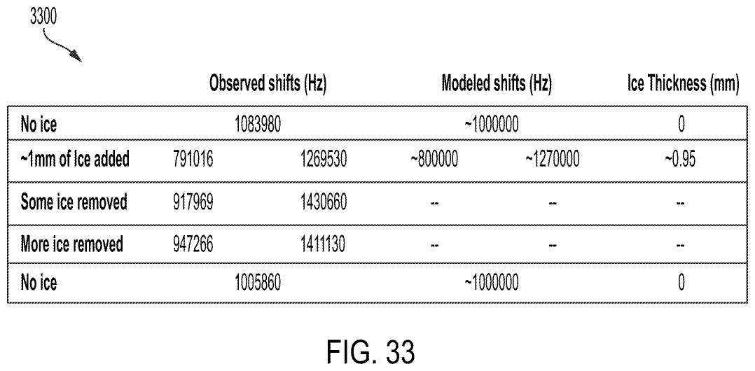

The 1 MHz transducer can be sensitive to frequencies in the range of 0.65 MHz to 1.59 MHz. Frequencies outside of this range may not be observed in the acquired acoustic signatures. When no ice is present, both the observed and modeled frequency can be around 1 MHz. When about 1 mm of ice (accreted layer) was added to an aluminum substrate surface, the observed fundamental frequency can shift to a lower frequency and a peak from a second harmonic can also appear. The addition of ice results in a shift of a fundamental frequency to a lower frequency as well, as the appearance of the second harmonic is within the observable frequency range. FIG. 32 illustrates a frequency-thickness graph 3200 generated by the frequency-thickness model. In the example of FIG. 32, the graph 3200 can be analyzed by the frequency-thickness model to determine expected frequencies with 1 mm of ice; the fundamental frequency occurs at about 0.8 MHz and the second harmonic occurs at about 1.2 MHz. As ice is removed and the layer of ice becomes thinner, the frequencies shift to higher frequencies, as disclosed herein. When the ice is completely removed, the resonance frequency can appear once again at about 1.0 MHz. FIG. 33 illustrates a table 3300 summarizing observed shifts with respect to one or more examples of FIGS. 26-29 and modeled shifts with respect to one or more examples of FIG. 32.

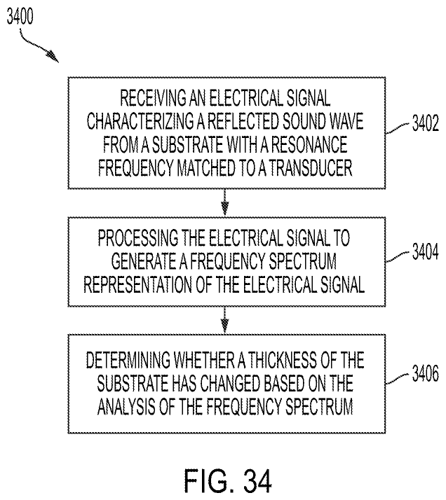

In view of the foregoing structural and functional features described above, an example method will be better appreciated with reference to FIG. 34. While, for purposes of simplicity of explanation, the example method of FIG. 34 is shown and described as executing serially, it is to be understood and appreciated that the present example is not limited by the illustrated order, as some actions could in other examples occur in different orders, multiple times and/or concurrently from that shown and described herein. Moreover, it is not necessary that all described actions be performed to implement the method.

FIG. 34 is an example of a method 3400 for determining whether a thickness of a substrate has changed. The substrate can correspond to the substrate 102, as shown in FIG. 1, or the substrate 208, as shown in FIG. 2. Thus, reference can be made to one or more examples of FIGS. 1-2 in the example of FIG. 34. The method 3400 can be implemented by the acoustic wave analysis system 100, as shown in FIG. 1. The method 3400 can begin at 3402, with the system 100 receiving an electrical signal (e.g., the electrical signal 114, as shown in FIG. 1) characterizing a reflected sound wave (e.g., the reflected sound wave 110, as shown in FIG. 1) from the substrate captured by a transducer (e.g., the transducer 104, as shown in FIG. 1) that has a resonance frequency that matches a resonance frequency of the substrate. At 3404, the electrical signal can be processed (e.g., by the frequency domain transformer 122, as shown in FIG. 1) to generate a frequency spectrum (e.g., the frequency spectrum 124, as shown in FIG. 1) representation of the electrical signal. At 3406, a determination (e.g., the substrate change detector 126, as shown in FIG. 1) can be made as to whether a thickness of the substrate has changed from a given thickness based on analysis of the frequency spectrum.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

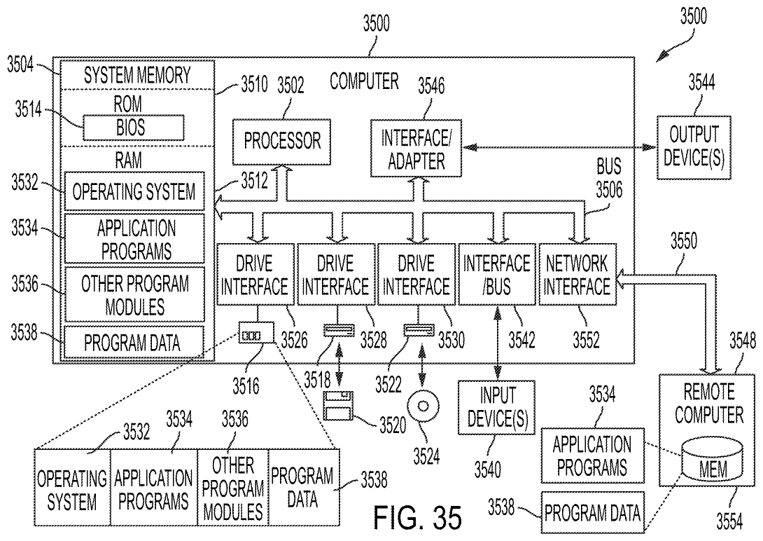

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system 3500 of FIG. 35. Thus, reference can be made to one or more examples of FIGS. 1-34 in the example of FIG. 35.

In this regard, FIG. 35 illustrates one example of a computer system 3500 that can be employed to execute one or more embodiments of the present disclosure. Computer system 3500 can be implemented on one or more general purpose networked computer systems, embedded computer systems, routers, switches, server devices, client devices, various intermediate devices/nodes or standalone computer systems. Additionally, computer system 3500 can be implemented on various mobile clients such as, for example, a personal digital assistant (PDA), laptop computer, pager, and the like, provided it includes sufficient processing capabilities.

Computer system 3500 includes processing unit 3502, system memory 3504, and system bus 3506 that couples various system components, including the system memory 3504, to processing unit 3502. Dual microprocessors and other multi-processor architectures also can be used as processing unit 3502. System bus 3506 may be any of several types of bus structure including a memory bus or memory controller, a peripheral bus, and a local bus using any of a variety of bus architectures. System memory 3504 includes read only memory (ROM) 3510 and random access memory (RAM) 3512. A basic input/output system (BIOS) 3514 can reside in ROM 3510 containing the basic routines that help to transfer information among elements within computer system 3500.

Computer system 3500 can include a hard disk drive 3516, magnetic disk drive 3518, e.g., to read from or write to removable disk 3520, and an optical disk drive 3522, e.g., for reading CD-ROM disk 3524 or to read from or write to other optical media. Hard disk drive 3516, magnetic disk drive 3518, and optical disk drive 3522 are connected to system bus 3506 by a hard disk drive interface 3526, a magnetic disk drive interface 3528, and an optical drive interface 3530, respectively. The drives and associated computer-readable media provide nonvolatile storage of data, data structures, and computer-executable instructions for computer system 3500. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and disclosed herein. A number of program modules may be stored in drives and RAM 3510, including operating system 3532, one or more application programs 3534, other program modules 3536, and program data 3538. In some examples, the application programs 3534 can include one or more modules (or block diagrams), or systems, as shown and disclosed herein, for example, with respect to FIGS. 1-2.

A user may enter commands and information into computer system 3500 through one or more input devices 3540, such as a pointing device (e.g., a mouse, touch screen), keyboard, microphone, joystick, game pad, scanner, and the like. These and other input devices are often connected to processing unit 3502 through a corresponding port interface 3542 that is coupled to the system bus, but may be connected by other interfaces, such as a parallel port, serial port, or universal serial bus (USB). One or more output devices 3544 (e.g., display, a monitor, printer, projector, or other type of displaying device) is also connected to system bus 3506 via interface 3546, such as a video adapter.

Computer system 3500 may operate in a networked environment using logical connections to one or more remote computers, such as remote computer 3548. Remote computer 3548 may be a workstation, computer system, router, peer device, or other common network node, and typically includes many or all the elements described relative to computer system 3500. The logical connections, schematically indicated at 3550, can include a local area network (LAN) and a wide area network (WAN). When used in a LAN networking environment, computer system 3500 can be connected to the local network through a network interface or adapter 3552. When used in a WAN networking environment, computer system 3500 can include a modem, or can be connected to a communications server on the LAN. The modem, which may be internal or external, can be connected to system bus 3506 via an appropriate port interface. In a networked environment, application programs 3534 or program data 3538 depicted relative to computer system 3500, or portions thereof, may be stored in a remote memory storage device 3554.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (SaaS, platform as a service (PaaS), and/or infrastructure as a service (IaaS)) and at least four deployment models (e.g., private cloud, community cloud, public cloud, and/or hybrid cloud). A cloud computing environment can be service oriented with a focus on statelessness, low coupling, modularity, and semantic interoperability.

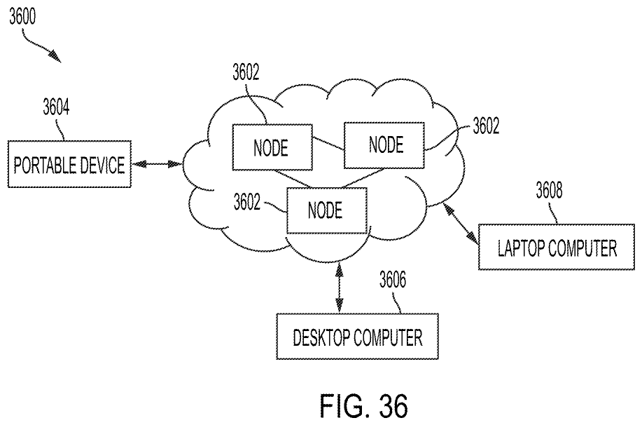

FIG. 36 is an example of a cloud computing environment 3600 that can be used for implementing one or more modules and/or systems in accordance with one or more examples, as disclosed herein. Thus, reference can be made to one or more examples of FIGS. 1-35 in the example of FIG. 36. As shown, cloud computing environment 3600 can include one or more cloud computing nodes 3602 with which local computing devices used by cloud consumers (or users), such as, for example, personal digital assistant (PDA), cellular, or portable device 3604, a desktop computer 3606, and/or a laptop computer 3608, may communicate. The computing nodes 3602 can communicate with one another. In some examples, the computing nodes 802 can be grouped (not shown) physically or virtually, in one or more networks, such as Private, Community, Public, or Hybrid clouds, or a combination thereof. This allows the cloud computing environment 3600 to offer infrastructure, platforms and/or software as services for which a cloud consumer does not need to maintain resources on a local computing device. The devices 3604-3608 are intended to be illustrative and that computing nodes 3602 and cloud computing environment 3600 can communicate with any type of computerized device over any type of network and/or network addressable connection (e.g., using a web browser). In some examples, the one or more computing nodes 3602 are used for implementing one or more examples disclosed herein for processing and computing data. Thus, in some examples, the one or more computing nodes can be used to implement modules, platforms, and/or systems, as disclosed herein.

In some examples, the cloud computing environment 3600 can provide one or more functional abstraction layers. It is understood that the cloud computing environment 3600 need not provide all of the one or more functional abstraction layers (and corresponding functions and/or components), as disclosed herein. For example, the cloud computing environment 3600 can provide a hardware and software layer that can include hardware and software components. Examples of hardware components include: mainframes; RISC (Reduced Instruction Set Computer) architecture based servers; servers; blade servers; storage devices; and networks and networking components. In some embodiments, software components include network application server software and database software.

In some examples, the cloud computing environment 3600 can provide a virtualization layer that provides an abstraction layer from which the following examples of virtual entities may be provided: virtual servers; virtual storage; virtual networks, including virtual private networks; virtual applications and operating systems; and virtual clients. In some examples, the cloud computing environment 3600 can provide a management layer that can provide the functions described below. For example, the management layer can provide resource provisioning that can provide dynamic procurement of computing resources and other resources that are utilized to perform tasks within the cloud computing environment. The management layer can also provide metering and pricing to provide cost tracking as resources are utilized within the cloud computing environment 3600, and billing or invoicing for consumption of these resources. In one example, these resources may include application software licenses. Security provides identity verification for cloud consumers and tasks, as well as protection for data and other resources. The management layer can also provide a user portal that provides access to the cloud computing environment 3600 for consumers and system administrators. The management layer can also provide service level management, which can provide cloud computing resource allocation and management such that required service levels are met. Service Level Agreement (SLA) planning and fulfillment can also be provided to provide pre-arrangement for, and procurement of, cloud computing resources for which a future requirement is anticipated in accordance with an SLA.

In some examples, the cloud computing environment 3600 can provide a workloads layer that provides examples of functionality for which the cloud computing environment 3600 may be utilized. Examples of workloads and functions which may be provided from this layer include: mapping and navigation; software development and lifecycle management; virtual classroom education delivery; data analytics processing; and transaction processing. Various embodiments of the present disclosure can utilize the cloud computing environment 3600.

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g. “about 2 to about 4” also discloses the range “from 2 to 4.” Generally, the terms “about” and “approximately” may refer to plus or minus 5-10% of the indicated number.

What has been described above include mere examples of systems, computer program products and computer-implemented methods. It is, of course, not possible to describe every conceivable combination of components, products and/or computer-implemented methods for purposes of describing this disclosure, but one of ordinary skill in the art can recognize that many further combinations and permutations of this disclosure are possible. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

The invention claimed is:

1. A system for detecting a change in a substrate comprising:
a transducer that is frequency matched to the substrate and to provide an electrical signal characterizing a reflected sound wave by the substrate; and
an acoustic wave analysis system to detect a change in a physical characteristic of the substrate.

2. The system of claim 1, wherein the physical characteristic is a thickness of the substrate.

3. The system of claim 1, wherein the acoustic wave analysis system is to detect a layer on the substrate.

4. The system of claim 3, wherein detection of the layer on the substrate corresponds to detecting the change in the physical characteristic of the substrate.

5. The system of claim 1, wherein the acoustic wave analysis system comprises:
a frequency domain transformer to convert the electrical signal from a time domain to a frequency domain to provide a frequency spectrum representation of the electrical signal; and
a substrate change detector to detect the change in the physical characteristic of the substrate based on the frequency spectrum.

6. The system of claim 5, wherein the change in the physical characteristic of the substrate correspond to one of a decrease in thickness of the substrate, a change in density of the substrate, and an increase in thickness of the substrate, the increase in the thickness of the substrate corresponding to a formation of a layer on the substrate.

7. The system of claim 1, wherein the substrate change detector outputs an alert in response to detecting the change in the physical characteristic.

8. The system of claim 7, wherein the alert is provided to another system or device in response to detected change in thickness.

9. The system of claim 1, wherein the acoustic wave analysis system is implemented on one or more computing platforms.

10. The system of claim 9, wherein the one or more computing platforms are part of a cloud computing environment.

11. The system of claim 1, wherein the transducer includes a piezoelectric material that is frequency matched to the substrate.

12. An ultrasonic transducer for detecting a change in a substrate comprising:
a first electrode;
a second electrode; and
a piezoelectric material between the first electrode and the second electrode, wherein the transducer is frequency matched to the substrate.

13. The transducer of claim 12, further comprising a backing material.

14. The transducer of claim 12, further comprising an acoustic matching layer.

15. A method comprising:
forming a piezoelectric material having defined properties so that a frequency bandwidth of the piezoelectric material includes a resonance frequency of the substrate; and
constructing a transducer with the formed piezoelectric material for monitoring the substrate.

16. The method of claim 15, wherein said forming comprising providing the piezoelectric material with a given thickness.

17. The method of claim 16, wherein said providing comprises one of three-dimensional (3D) printing, molding, or thermal pressing the piezoelectric material according to thickness criteria specifying the given thickness for the piezoelectric material.

18. The method of claim 15, wherein the defined properties include one of a thickness, an elasticity, a porosity, a composition, a density, and/or a shape of the piezoelectric material.

19. The method of claim 15, wherein said constructing the transducer comprises incorporating first and second electrodes, such that the piezoelectric material is between the first electrode and the second electrode.

20. The method of claim 15, wherein said constructing the transducer comprises incorporating at least one of a backing material and an acoustic matching layer.
